(19) United States
(12) Patent Application Publication
(10) Pub. No.: US 2026/0301786 A1
(43) Pub. Date: Oct. 1, 2026

(54) SEMICONDUCTOR SYSTEM PERFORMING TRAINING OPERATION

(71) Applicant: SK hynix Inc., Gyeonggi-do (KR)

(72) Inventors: Joon Hong PARK, Gyeonggi-do (KR); Sang Sic YOON, Gyeonggi-do (KR)

(21) Appl. No.: 19/263,523

(22) Filed: Jul. 9, 2025

(30) Foreign Application Priority Data
Mar. 27, 2025 (KR) 10-2025-0039729

(51) Int. Cl. G11C 7/22; G11C 7/10; G11C 29/52

(52) U.S. Cl. CPC G11C 7/222; G11C 7/1066; G11C 7/1069; G11C 7/1096; G11C 29/52

(57) ABSTRACT

A semiconductor system includes a controller and a memory device. The controller outputs first and second data during a write operation, receives the first and second data during a read operation, and tunes a delay quantity of output of the first and second data. The memory device stores the first data in a data storage circuit and the second data in a meta storage circuit during the write operation, and outputs, to the controller, the first and second data from the data storage circuit and the meta storage circuit during the read operation.

### CROSS-REFERENCE TO RELATED APPLICATION

This application claims priority under 35 U.S.C. § 119(a) to Korean Patent Application No. 10-2025-0039729, filed on Mar. 27, 2025, the entire contents of which are incorporated herein by reference.

### BACKGROUND

The embodiments of the present disclosure generally relate to a semiconductor system that learns data and a data clock, by using a plurality of memory cells and a plurality of registers.

Recently, to increase the operating speed of a semiconductor device, DDR2, DDR3, DDR4, and DDR5 methods of inputting and outputting data of multiple bits every clock cycle are used. When the input and output speed of data are increased, a probability of an error occurring during the data transmission process also increases. Accordingly, a separate device and method for ensuring the reliability of data transmission are additionally required.

A method for ensuring the reliability of data transmission is used by generating error information that can be used to check whether an error has occurred each time data is transmitted, and by transmitting this error information along with the data. The error information may be generated based on an error detection code (EDC) capable of detecting an error and an error correction code (ECC) capable of correcting the detected error. The error information may be input and output through a path along which data to be stored are input and output, and another path along which meta data are input and output.

### SUMMARY

In an embodiment of the present disclosure, a semiconductor system may include a controller configured to output first and second groups of data after the start of a write operation of a training operation, receive the first and second groups of data after the start of a read operation of the training operation, and tune a delay quantity by which the first and second groups of data are output, and a memory device configured to receive the first group of data through a first group of data transfer circuits that input and output data, store the first group of data in a data storage circuit, receive the second group of data through a second group of data transfer circuits that input and output error information, and store the second group of data in a meta storage circuit after the start of the write operation of the training operation data, and further configured to output the first group of data stored in the data storage circuit to the controller and output the second group of data stored in the meta storage circuit to the controller after the start of the read operation of the training operation.

In an embodiment of the present disclosure, a memory device may include a data input and output circuit configured to generate a first group of transfer data by receiving a first group of data and generate a second group of transfer data by receiving a second group of data, after the start of a write operation of a training operation, and further configured to generate the first group of data by receiving the first group of transfer data generated from internal data and generate the second group of data by receiving the second group of transfer data, after the start of a read operation of the training operation, a data storage circuit including a plurality of banks, configured to store the internal data generated from the first group of transfer data in a bank selected from among the plurality of banks based on the address after the start of the write operation of the training operation and output the internal data stored in the bank selected from among the plurality of banks based on the address after the start of the read operation of the training operation, and a meta storage circuit including a plurality of registers, configured to store the second group of data in a register selected from among the plurality of registers based on the address after the start of the write operation of the training operation and output the second group of data stored in the register selected from among the plurality of registers based on the address after the start of the read operation of the training operation.

In an embodiment of the present disclosure, a memory device may include a first data transfer circuit configured to receive first data and store the first data in a write pipe circuit and a read pipe circuit after the start of a write operation of a training operation and output the first data stored in the read pipe circuit after the start of a read operation of the training operation, a second data transfer circuit configured to generate transfer data by receiving second data after the start of the write operation of the training operation, generate the second data from test meta data and output the second data after the start of the read operation of the training operation, and a meta storage circuit including a plurality of registers, configured to store the transfer data in a register selected from among the plurality of registers based on an address after the start of the write operation of the training operation and output the transfer data stored in the register selected from among the plurality of registers based on the address as the test meta data after the start of the read operation of the training operation.

### BRIEF DESCRIPTION OF THE DRAWINGS

FIG. 1 is a block diagram illustrating a construction of a semiconductor system according to an embodiment of the present disclosure.

FIG. 2 is a block diagram illustrating a construction of a memory device included in the semiconductor system illustrated in FIG. 1, according to an embodiment of the present disclosure.

FIG. 3 is a block diagram illustrating a construction of a data input and output circuit included in the memory device illustrated in FIG. 2, according to an embodiment of the present disclosure.

FIG. 4 is a block diagram illustrating a construction of a first data transfer circuit included in the data input and output circuit illustrated in FIG. 3, according to an embodiment of the present disclosure.

FIG. 5 is a block diagram illustrating a construction of an eleventh data transfer circuit included in the data input and output circuit illustrated in FIG. 3, according to an embodiment of the present disclosure.

FIG. 6 is a block diagram illustrating a construction of a data control circuit included in the memory device illustrated in FIG. 2, according to an embodiment of the present disclosure.

FIG. 7 is a block diagram illustrating a construction of a data storage circuit included in the memory device illustrated in FIG. 2, according to an embodiment of the present disclosure.

FIG. 8 is a block diagram illustrating a construction of a meta storage circuit included in the memory device illustrated in FIG. 2, according to an embodiment of the present disclosure.

FIG. 9 is a block diagram illustrating a construction of a register circuit included in the meta storage circuit illustrated in FIG. 8, according to an embodiment of the present disclosure.

FIG. 10 is a block diagram illustrating a construction of a first register included in the register circuit illustrated in FIG. 9, according to an embodiment of the present disclosure.

FIG. 11 is a diagram of a data map for describing data according to an embodiment of the present disclosure.

FIG. 12 is a diagram for describing data that are input and output based on an address according to an embodiment of the present disclosure.

FIGS. 13 and 14 are diagrams for describing a normal operation according to an embodiment of the present disclosure.

FIGS. 15 and 16 are diagrams for describing a meta write operation and meta read operation of the normal operation according to an embodiment of the present disclosure.

FIGS. 17 and 18 are diagrams for describing a first mode of a training operation according to an embodiment of the present disclosure.

FIGS. 19 and 20 are diagrams for describing a second mode of the training operation according to an embodiment of the present disclosure.

FIGS. 21 and 22 are diagrams for describing a third mode of the training operation according to an embodiment of the present disclosure.

FIG. 23 is a flowchart for describing the first mode and second mode of the training operation according to an embodiment of the present disclosure.

FIG. 24 is a flowchart for describing the third mode of the training operation according to an embodiment of the present disclosure.

### DETAILED DESCRIPTION

In the descriptions of the following embodiments, terms such as “first” and “second,” which are used to distinguish various components, are not intended to limit the components. For example, a first component may be referred to as a second component, and vice versa.

When one component is referred to as being “coupled” or “connected” to another component, it should be understood that the components may be directly coupled or connected to each other or coupled or connected to each other through another component interposed therebetween. In contrast, when one component is referred to as being “directly coupled” or “directly connected” to another component, it should be understood that the components are directly coupled or connected to each other without another component interposed therebetween.

A “logic high level” and a “logic low level” are used to describe the logic levels of signals. A signal having a “logic high level” is distinguished from a signal having a “logic low level.” For example, a signal having a first voltage may correspond to a signal having a “logic high level,” and a signal having a second voltage may correspond to a signal having a “logic low level.” According to an embodiment, a “logic high level” may be set to a voltage higher than a “logic low level.” According to an embodiment, the logic levels of signals may be set to different logic levels or opposite logic levels. For example, a signal having a logic high level may be set to have a logic low level in some embodiments, and a signal having a logic low level may be set to have a logic high level in some embodiments.

Hereafter, the scope of the present disclosure will be described in more detail through embodiments. However, the scope of the present disclosure is not intended to be limited by the embodiments.

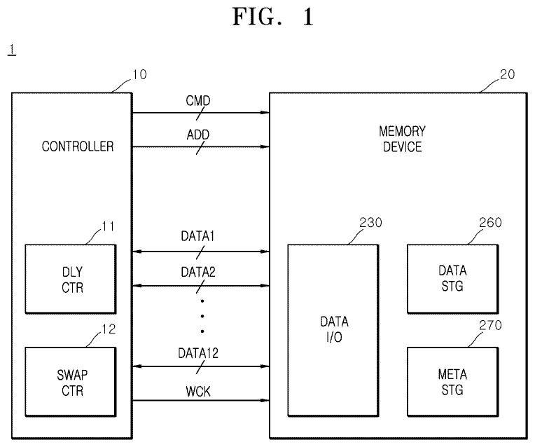

As illustrated in FIG. 1, a semiconductor system 1 according to an embodiment of the present disclosure, may include a controller 10 and a memory device 20.

The controller 10 may include a delay quantity control circuit (DLY CTR) 11 and a swap control circuit (SWAP CTR) 12.

The controller 10 may transmit a command CMD that controls a normal operation and a training operation to the memory device 20. The controller 10 may transmit an address ADD that controls the normal operation and the training operation to the memory device 20.

After the start of write operations of the normal operation and the training operation, the delay quantity control circuit 11 may output first to twelfth data DATA1 to DATA12. After the start of a write operation of the training operation, the delay quantity control circuit 11 may repeatedly output the first to twelfth data DATA1 to DATA12. After the start of read operations of the normal operation and the training operation, the delay quantity control circuit 11 may receive the first to twelfth data DATA1 to DATA12. After the start of a read operation of the training operation, the delay quantity control circuit 11 may repeatedly receive the first to twelfth data DATA1 to DATA12. After the start of write operations and read operations of the normal operation and the training operation, the delay quantity control circuit 11 may output a data clock WCK that strobes the first to twelfth data DATA1 to DATA12. The delay quantity control circuit 11 may tune a delay quantity by which the first to twelfth data DATA1 to DATA12 are output so that timing at which the first to twelfth data DATA1 to DATA12 are output and timing at which the data clock WCK is output are matched in the training operation. When a logic level combination of the first to twelfth data DATA1 to DATA12 that are output in a write operation of the training operation and a logic level combination of the first to twelfth data DATA1 to DATA12 that are received in a read operation of the training operation are different from each other, the delay quantity control circuit 11 may output the first to twelfth data DATA1 to DATA12 by decreasing or increasing the delay quantity by which the first to twelfth data DATA1 to DATA12 are output.

The swap control circuit 12 may control the training operation on specific data, among the first to twelfth data DATA1 to DATA12. In a third mode MODE3 of the training operation, the swap control circuit 12 may control the training operation to be performed on any one of the first to twelfth data DATA1 to DATA12 through a meta storage circuit (META STG) 270. For example, in the third mode of the training operation, the swap control circuit 12 may control the training operation to be performed on the first data DATA1 through the meta storage circuit 270, and may control the training operation to be performed on the second to twelfth data DATA2 to DATA12 through a pipe circuit included in a data input and output circuit (DATA I/O) 230.

The controller 10 may transmit the command CMD that controls the normal operation and the training operation to the memory device 20. The controller 10 may transmit the address ADD that controls the normal operation and the training operation to the memory device 20. After the start of write operations of the normal operation and the training operation, the controller 10 may transmit the first to twelfth data DATA1 to DATA12 to the memory device 20. After the start of a write operation of the training operation, the controller 10 may repeatedly transmit the first to twelfth data DATA1 to DATA12 to the memory device 20. After the start of write operations and read operations of the normal operation and the training operation, the controller 10 may transmit the data clock WCK that strobes the first to twelfth data DATA1 to DATA12 to the memory device 20. After the start of read operations of the normal operation and the training operation, the controller 10 may receive the first to twelfth data DATA1 to DATA12 from the memory device 20. After the start of a read operation of the training operation, the controller 10 may repeatedly receive the first to twelfth data DATA1 to DATA12 from the memory device 20. In the training operation, the controller 10 may tune a delay quantity by which the first to twelfth data DATA1 to DATA12 are output so that timing at which the first to twelfth data DATA1 to DATA12 are output and timing at which the data clock WCK is output are matched. For example, when a logic level combination of the first to twelfth data DATA1 to DATA12 that are output in a write operation of the training operation and a logic level combination of the first to twelfth data DATA1 to DATA12 that are received in a read operation of the training operation are different from each other, the controller 10 may output the first to twelfth data DATA1 to DATA12 by decreasing or increasing the delay quantity by which the first to twelfth data DATA1 to DATA12 are output.

The memory device 20 may include the data input and output circuit (DATA I/O) 230, a data storage circuit (DATA STG) 260, and the meta storage circuit (META STG) 270.

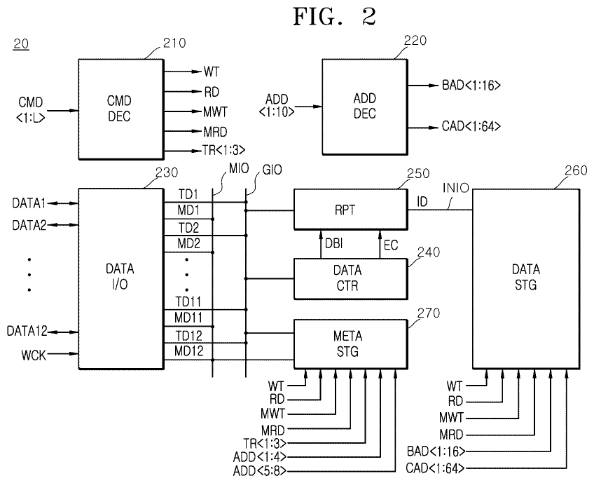

After the start of write operations of the normal operation and the training operation, the data input and output circuit 230 may receive the first to twelfth data DATA1 to DATA12. After the start of write operations of the normal operation and the training operation, the data input and output circuit 230 may store the first to twelfth data DATA1 to DATA12 in the pipe circuit, and may output the first to twelfth data DATA1 to DATA12 stored in the data storage circuit 260 and the meta storage circuit 270. After the start of read operations of the normal operation and the training operation, the data input and output circuit 230 may output the first to twelfth data DATA1 to DATA12. After the start of the read operations of the normal operation and the training operation, the data input and output circuit 230 may store internal data (ID in FIG. 2) in the pipe circuit, and may output the stored internal data (ID in FIG. 2) as the first to twelfth data DATA1 to DATA12.

After the start of write operations of the normal operation and the training operation, the data storage circuit 260 may receive the first to eleventh data DATA1 to DATA11 from the data input and output circuit 230 and store the first to eleventh data DATA1 to DATA11 based on the address ADD. After the start of read operations of the normal operation and the training operation, the data storage circuit 260 may output the first to eleventh data DATA1 to DATA11 stored in the data storage circuit 260 to the data input and output circuit 230 based on the address ADD.

After the start of write operations of the normal operation and the training operation, the meta storage circuit 270 may receive the eleventh and twelfth data DATA11 and DATA12 from the data input and output circuit 230 and store the eleventh and twelfth data DATA11 and DATA12 based on the address ADD. After the start of read operations of the normal operation and the training operation, the meta storage circuit 270 may output the eleventh and twelfth data DATA11 and DATA12 stored in the meta storage circuit 270 to the data input and output circuit 230 based on the address ADD.

The memory device 20 may perform the normal operation and the training operation based on the command CMD and the address ADD. After the start of a write operation of the normal operation, the memory device 20 may store the first to twelfth data DATA1 to DATA12 in the data storage circuit 260 and the meta storage circuit 270 based on the command CMD and the address ADD. After the start of a read operation of the normal operation, the memory device 20 may output the first to twelfth data DATA1 to DATA12 stored in the data storage circuit 260 and the meta storage circuit 270 based on the command CMD and the address ADD. After the start of a write operation of the training operation, the memory device 20 may repeatedly store the first to twelfth data DATA1 to DATA12 in the data storage circuit 260 and the meta storage circuit 270 based on the command CMD and the address ADD. After the start of a read operation of the training operation, the memory device 20 may repeatedly output the first to twelfth data DATA1 to DATA12 stored in the data storage circuit 260 and the meta storage circuit 270 based on the command CMD and the address ADD.

FIG. 2 is a block diagram illustrating a construction of the memory device 20 included in the semiconductor system 1 illustrated in FIG. 1, according to an embodiment of the present disclosure. The memory device 20 may include a command decoding circuit (CMD DEC) 210, an address decoding circuit (ADD DEC) 220, the data input and output circuit (DATA I/O) 230, a data control circuit (DATA CTR) 240, a repeater (RPT) 250, the data storage circuit (DATA STG) 260, and the meta storage circuit (META STG) 270.

The command decoding circuit 210 may generate a write signal WT, a read signal RD, a meta write signal MWT, a meta read signal MRD, and first to third bits TR<1:3> of a training signal by decoding first to L-th bits CMD<1:L> of the command. The command decoding circuit 210 may generate the write signal WT that is generated when the first to L-th bits CMD<1:L> of the command have a logic level combination for performing write operations of the normal operation and the training operation. The command decoding circuit 210 may generate the read signal RD that is generated when the first to L-th bits CMD<1:L> of the command have a logic level combination for performing read operations of the normal operation and the training operation. The command decoding circuit 210 may generate the meta write signal MWT that is generated when the first to L-th bits CMD<1:L> of the command have a logic level combination for performing a meta write operation of the normal operation. The command decoding circuit 210 may generate the meta read signal MRD that is generated when the first to L-th bits CMD<1:L> of the command have a logic level combination for performing a meta read operation of the normal operation. The command decoding circuit 210 may generate the first bit TR<1> of the training signal that is generated to perform a first mode MODE1 by decoding a specific bit, among the first to L-th bits CMD<1:L> of the command. The command decoding circuit 210 may generate the second bit TR<2> of the training signal that is generated to perform a second mode MODE2 by decoding a specific bit, among the first to L-th bits CMD<1:L> of the command. The command decoding circuit 210 may generate the third bit TR<3> of the training signal that is generated to perform the third mode by decoding a specific bit, among the first to L-th bits CMD<1:L> of the command.

The address decoding circuit 220 may generate first to sixteenth bits BAD<1:16> of a bank address and first to sixty-fourth bits CAD<1:64> of a column address by decoding first to tenth bits ADD<1:10> of the address. The address decoding circuit 220 may generate the first to sixteenth bits BAD<1:16> of the bank address that are selectively generated by decoding the first to fourth bits ADD<1:4> of the address. The address decoding circuit 220 may generate the first to sixty-fourth bits CAD<1:64> of the column address that are selectively generated by decoding the fifth to tenth bits ADD<5:10> of the address.

After the start of write operations of the normal operation and the training operation, the data input and output circuit 230 may receive the first to twelfth data DATA1 to DATA12. After the start of write operations of the normal operation and the training operation, the data input and output circuit 230 may receive the first to twelfth data DATA1 to DATA12 in synchronization with a rising edge and falling edge of the data clock WCK. The data input and output circuit 230 may generate first to tenth transfer data TD1 to TD10 from the received first to tenth data DATA1 to DATA10. The data input and output circuit 230 may output the first to tenth transfer data TD1 to TD10 to a data input and output line GIO. The data input and output circuit 230 may generate eleventh and twelfth transfer data TD11 and TD12 from the received eleventh and twelfth data DATA11 and DATA12. The data input and output circuit 230 may output the eleventh and twelfth transfer data TD11 and TD12 to the data input and output line GIO and a meta input and output line MIO. After the start of read operations of the normal operation and the training operation, the data input and output circuit 230 may receive the first to twelfth transfer data TD1 to TD12. After the start of read operations of the normal operation and the training operation, the data input and output circuit 230 may receive the first to twelfth transfer data TD1 to TD12 in synchronization with a rising edge and falling edge of the data clock WCK. The data input and output circuit 230 may generate the first to twelfth data DATA1 to DATA12 from the received first to twelfth transfer data TD1 to TD12. In the third mode of a write operation of the training operation, the data input and output circuit 230 may store the remaining data in a write pipe circuit and a read pipe circuit except specific data, among the first to twelfth data DATA1 to DATA12. In the third mode of a write operation of the training operation, the data input and output circuit 230 may generate any one of the first to twelfth transfer data TD1 to TD12 from specific data, among the first to twelfth data DATA1 to DATA12. In the third mode of a read operation of the training operation, the data input and output circuit 230 may output the remaining data stored in the write pipe circuit and the read pipe circuit except specific data, among the first to twelfth data DATA1 to DATA12. In the third mode of a read operation of the training operation, the data input and output circuit 230 may generate any one of the first to twelfth data DATA1 to DATA12 from any one of the first to twelfth test meta data MD1 to MD12.

The first to tenth data DATA1 to DATA10 may be set as a first group of data. The first group of data may be set as a signal to be stored in the data storage circuit 260. The eleventh and twelfth data DATA11 and DATA12 may be set as a second group of data. The second group of data may be set as a signal including error information of the first group of data and data inversion information for transmitting the first group of data by inverting the first group of data.

After the start of the normal operation, the data control circuit 240 may generate a data inversion signal DBI based on data inversion information that is included in bits included in the eleventh transfer data TD11 and bits included in the twelfth transfer data TD12. After the start of the normal operation, the data control circuit 240 may generate an error correction signal EC based on error information that is included in bits included in the eleventh transfer data TD11 and bits included in the twelfth transfer data TD12. The error correction signal EC may be generated to include multiple bits.

The data inversion information may be set as information for outputting the first to tenth data DATA1 to DATA10 by inverting the first to tenth data DATA1 to DATA10 when the number of logic high levels, among bits included in the first to tenth data DATA1 to DATA10, is greater than ½ of a total number of logic high levels. The error information may be set as a parity signal for data including an error, among the first to tenth data DATA1 to DATA10. The parity signal may be set as a signal that is generated through a common error correction code (ECC).

After the start of write operations of the normal operation and the training operation, the repeater 250 may generate the internal data ID based on the first to eleventh transfer data TD1 to TD11 loaded onto the data input and output line GIO. After the start of write operations of the normal operation and the training operation, the repeater 250 may output the internal data ID to an internal input and output line INIO. After the start of a write operation of the normal operation, when the data inversion signal DBI is generated, the repeater 250 may generate the internal data ID by inverting the first to eleventh transfer data TD1 to TD11, and may output the internal data ID to the internal input and output line INIO. After the start of a write operation of the normal operation, the repeater 250 may generate the internal data ID by correcting a bit including an error, among the first to eleventh transfer data TD1 to TD11, based on the plurality of error correction signals EC, and may output the internal data ID to the internal input and output line INIO. An operation of correcting, by the repeater 250, a bit including an error, among the first to eleventh transfer data TD1 to TD11, may mean an operation of inverting the logic level of a bit including an error, among the first to eleventh transfer data TD1 to TD11.

After the start of read operations of the normal operation and the training operation, the repeater 250 may generate the first to eleventh transfer data TD1 to TD11 based on the internal data ID loaded onto the internal input and output line INIO. The repeater 250 may output the first to eleventh transfer data TD1 to TD11 to the data input and output line GIO.

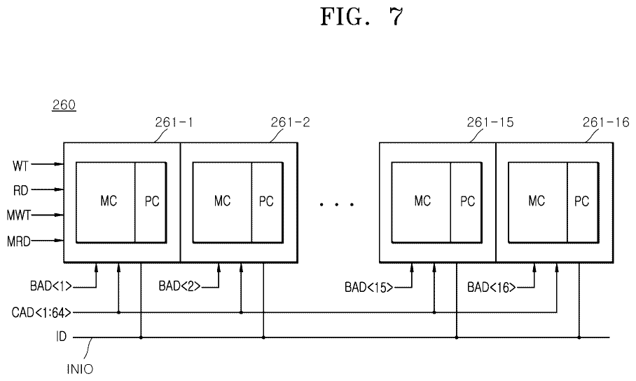

The data storage circuit 260 may include first to sixteenth banks (261-1 to 261-16 in FIG. 7). When the write signal WT is generated, the data storage circuit 260 may store the internal data ID loaded onto the internal input and output line INIO in a memory cell region (MC in FIG. 7) of a bank selected from among the first to sixteenth banks (261-1 to 261-16 in FIG. 7) based on the first to sixteenth bits BAD<1:16> of the bank address and the first to sixty-fourth bits CAD<1:64> of the column address. When the read signal RD is generated, the data storage circuit 260 may output the internal data ID stored in the memory cell region MC of a bank selected from among the first to sixteenth banks (261-1 to 261-16 in FIG. 7) to the internal input and output line INIO based on the first to sixteenth bits BAD<1:16> of the bank address and the first to sixty-fourth bits CAD<1:64> of the column address.

When the meta write signal MWT is generated, the data storage circuit 260 may store the internal data ID loaded onto the internal input and output line INIO in a parity cell region (PC in FIG. 7) of a bank selected from among the first to sixteenth banks (261-1 to 261-16 in FIG. 7) based on the first to sixteenth bits BAD<1:16> of the bank address and the first to sixty-fourth bits CAD<1:64> of the column address. When the meta read signal MRD is generated, the data storage circuit 260 may output the internal data ID stored in the parity cell region (PC in FIG. 7) of a bank selected from among the first to sixteenth banks (261-1 to 261-16 in FIG. 7) to the internal input and output line INIO based on the first to sixteenth bits BAD<1:16> of the bank address and the first to sixty-fourth bits CAD<1:64> of the column address.

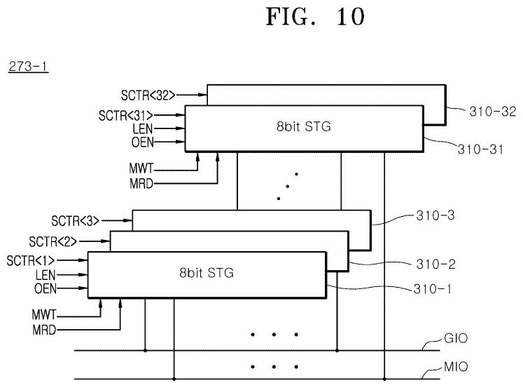

The meta storage circuit 270 may include first to sixteenth register circuits (1^{st} REG to 16^{th} REG) (273-1 to 273-16 in FIG. 10). After the start of write operations of the normal operation and the training operation, the meta storage circuit 270 may store the eleventh and twelfth transfer data TD11 and TD12, which are loaded onto the meta input and output line MIO, in a register circuit selected from among the first to sixteenth register circuits (273-1 to 273-16 in FIG. 10) based on the first to third bits TR<1:3> of the training signal and the first to eighth bits ADD<1:8> of the address. After the start of read operations of the normal operation and the training operation, the meta storage circuit 270 may generate the eleventh and twelfth test meta data MD11 and MD12 from the eleventh and twelfth transfer data TD11 and TD12 stored in a register circuit selected from among the first to sixteenth register circuits (273-1 to 273-16 in FIG. 10) based on the first to third bits TR<1:3> of the training signal and the first to eighth bits ADD<1:8> of the address. After the start of read operations of the normal operation and the training operation, the meta storage circuit 270 may output the eleventh and twelfth test meta data MD11 and MD12 to the meta input and output line MIO. In the third mode of a write operation of the training operation, the meta storage circuit 270 may store any one of the first to twelfth transfer data TD1 to TD12. In the third mode of a read operation of the training operation, the meta storage circuit 270 may generate any one of the first to twelfth test meta data MD1 to MD12 from any one of the first to twelfth transfer data TD1 to TD12 stored in the meta storage circuit 270. In the third mode of a read operation of the training operation, the meta storage circuit 270 may output any one of the first to twelfth test meta data MD1 to MD12 to the meta input and output line MIO.

When the meta write signal MWT is generated, the meta storage circuit 270 may output the eleventh and twelfth transfer data TD11 and TD12 stored in a register circuit selected from among the first to sixteenth register circuits (273-1 to 273-16 in FIG. 10) to the data input and output line GIO based on the first to eighth bits ADD<1:8> of the address. When the meta read signal MRD is generated, the meta storage circuit 270 may store the eleventh and twelfth transfer data TD11 and TD12 loaded onto the data input and output line GIO in a register circuit selected from among the first to sixteenth register circuits (273-1 to 273-16 in FIG. 10) based on the first to eighth bits ADD<1:8> of the address.

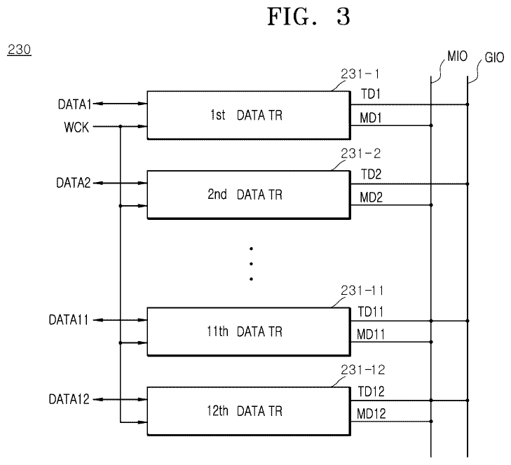

FIG. 3 is a block diagram illustrating a construction of the data input and output circuit 230 included in the memory device 20 illustrated in FIG. 2, according to an embodiment of the present disclosure. The data input and output circuit 230 may include first to twelfth data transfer circuits (1^{st} DATA TR to 12^{th} DATA TR) 231-1 to 231-12.

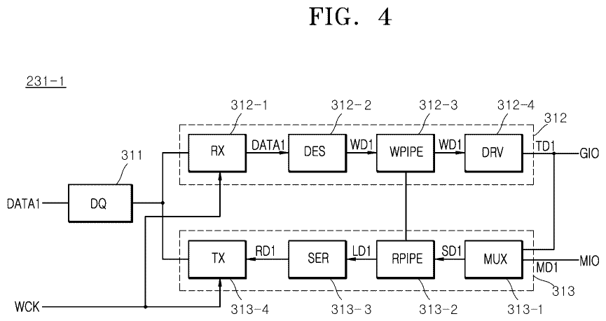

After the start of write operations of the normal operation and the training operation, the first data transfer circuit 231-1 may receive the first data DATA1 in synchronization with the data clock WCK. After the start of write operations of the normal operation and the training operation, the first data transfer circuit 231-1 may store the first data DATA1 that are received in synchronization with the data clock WCK in a write pipe circuit (WPIPE) (312-3 in FIG. 4). After the start of write operations of the normal operation and the training operation, the first data transfer circuit 231-1 may generate the first transfer data TD1 from the first data DATA1 stored in the write pipe circuit (312-3 in FIG. 4), and may output the first transfer data TD1 to the data input and output line GIO. After the start of read operations of the normal operation and the training operation, the first data transfer circuit 231-1 may receive the first transfer data TD1 loaded onto the data input and output line GIO in synchronization with the data clock WCK. After the start of read operations of the normal operation and the training operation, the first data transfer circuit 231-1 may store the first transfer data TD1 that are received in synchronization with the data clock WCK in a read pipe circuit (RPIPE) (313-2 in FIG. 4). After the start of read operations of the normal operation and the training operation, the first data transfer circuit 231-1 may generate the first data DATA1 from the first transfer data TD1 stored in the read pipe circuit (313-2 in FIG. 4), and may output the first data DATA1. In the third mode of the training operation, after the start of a write operation of the training operation, the first data transfer circuit 231-1 may store the first data DATA1 stored in the write pipe circuit (312-3 in FIG. 4) in the read pipe circuit (313-2 in FIG. 4) under the control of the swap control circuit 12. In the third mode of the training operation, the first data transfer circuit 231-1 may output the first data DATA1 stored in the read pipe circuit (313-2 in FIG. 4) under the control of the swap control circuit 12. In the third mode of the training operation, after the start of a read operation, the first data transfer circuit 231-1 may receive the first test meta data MD1 loaded onto the meta input and output line MIO under the control of the swap control circuit 12. In the third mode of the training operation, after the start of a read operation, the first data transfer circuit 231-1 may generate the first data DATA1 from the first test meta data MD1 received in synchronization with the data clock WCK, and may output the first data DATA1.

After the start of write operations of the normal operation and the training operation, the second data transfer circuit 231-2 may receive the second data DATA2 in synchronization with the data clock WCK. After the start of write operations of the normal operation and the training operation, the second data transfer circuit 231-2 may store the second data DATA2 received in synchronization with the data clock WCK in the write pipe circuit (not illustrated). After the start of write operations of the normal operation and the training operation, the second data transfer circuit 231-2 may generate the second transfer data TD2 from the second data DATA2 stored in the write pipe circuit (not illustrated), and may output the second transfer data TD2 to the data input and output line GIO. After the start of read operations of the normal operation and the training operation, the second data transfer circuit 231-2 may receive the second transfer data TD2 loaded onto the data input and output line GIO in synchronization with the data clock WCK. After the start of read operations of the normal operation and the training operation, the second data transfer circuit 231-2 may store the second transfer data TD2 that are received in synchronization with the data clock WCK in the read pipe circuit (not illustrated). After the start of read operations of the normal operation and the training operation, the second data transfer circuit 231-2 may generate the second data DATA2 from the second transfer data TD2 stored in the read pipe circuit (not illustrated), and may output the second data DATA2. In the third mode of the training operation, after the start of a write operation of the training operation, the second data transfer circuit 231-2 may store the second data DATA2 stored in the write pipe circuit (not illustrated) in the read pipe circuit (not illustrated). In the third mode of the training operation, the second data transfer circuit 231-2 may output the second data DATA2 stored in the read pipe circuit (not illustrated) under the control of the swap control circuit 12. In the third mode of the training operation, after the start of a read operation, the second data transfer circuit 231-2 may receive the second test meta data MD2 loaded onto the meta input and output line MIO under the control of the swap control circuit 12. In the third mode of the training operation, after the start of a read operation, the second data transfer circuit 231-2 may generate the second data DATA2 from the second test meta data MD2 received in synchronization with the data clock WCK, and may output the second data DATA2.

Only data that are input to and output from each of the third to twelfth data transfer circuits 231-3 to 231-12 are different from the data that are input to and output from each of the first and second data transfer circuits 231-1 and 231-2. Each of the third to twelfth data transfer circuits 231-3 to 231-12 is implemented with the same circuit as each of the first and second data transfer circuits 231-1 and 231-2 and performs the same operation as each of the first and second data transfer circuits 231-1 and 231-2, and thus a detailed description thereof is omitted.

The first to tenth data transfer circuits 231-1 to 231-10 may be set as a first group of data transfer circuits that generate a first group of transfer data TD1 to TD10 from the first group of data DATA1 to DATA10. The eleventh and twelfth data transfer circuits 231-11 and 231-12 may be set as a second group of data transfer circuits that generate a second group of transfer data TD11 and TD12 from the second group of data DATA11 and DATA12.

FIG. 4 is a block diagram illustrating a construction of the first data transfer circuit 231-1 included in the data input and output circuit 230 illustrated in FIG. 3, according to an embodiment of the present disclosure. The first data transfer circuit 231-1 may include a first pad (DQ) 311, a first write transfer circuit 312, and a first read transfer circuit 313.

After the start of write operations of the normal operation and the training operation, the first pad 311 may receive the first data DATA1 and output the first data DATA1 to the first write transfer circuit 312. After the start of read operations of the normal operation and the training operation, the first pad 311 may receive first read data RD1 from the first read transfer circuit 313 and output the first read data RD1 as the first data DATA1.

The first write transfer circuit 312 may include a first receiver (RX) 312-1, a first parallel conversion circuit (DES) 312-2, the first write pipe circuit (WPIPE) 312-3, and a first driver (DRV) 312-4.

The first receiver 312-1 may receive the first data DATA1 through the first pad 311 in synchronization with a rising edge and falling edge of the write clock WCK. The first receiver 312-1 may output the first data DATA1 received in synchronization with a rising edge and falling edge of the write clock WCK to the first parallel conversion circuit 312-2.

The first parallel conversion circuit 312-2 may convert the first data DATA1 that are input in series through the first receiver 312-1 in parallel. The first parallel conversion circuit 312-2 may generate first write data WD1 from the first data DATA1 that have been converted in parallel, and may output the first write data WD1 to the first write pipe circuit 312-3.

The first write pipe circuit 312-3 may latch the first write data WD1 that have been converted in parallel. The first write pipe circuit 312-3 may output the latched first write data WD1 to the first driver 312-4. In the third mode of the training operation, the first write pipe circuit 312-3 may output the first write data WD1 stored in the first write pipe circuit 312-3 to the first read pipe circuit 313-2 under the control of the swap control circuit 12.

The first driver 312-4 may generate the first transfer data TD1 based on the first write data WD1. The first driver 312-4 may output the first transfer data TD1 to the plurality of data input and output lines GIO. The first driver 312-4 may output the first transfer data TD1 to the plurality of data input and output lines GIO by driving the plurality of data input and output lines GIO based on the logic levels of bits included in the first transfer data TD1.

The first read transfer circuit 313 may include a first multiplexer (MUX) 313-1, the first read pipe circuit (RPIPE) 313-2, a first serial conversion circuit (SER) 313-3, and a first transmitter (TX) 313-4.

The first multiplexer 313-1 may receive any one of the first transfer data TD1 loaded onto the data input and output line GIO from the data storage circuit 260 and the first test meta data MD1 loaded onto the meta input and output line MIO from the meta storage circuit 270, and may output any one of the first transfer data TD1 and the first test meta data MD1 as first selection data SD1. In the first and second modes of the normal operation and the training operation, the first multiplexer 313-1 may receive the first transfer data TD1 loaded onto the data input and output line GIO from the data storage circuit 260 and output the first transfer data TD1 as the first selection data SD1 under the control of the swap control circuit 12. In the third mode of the training operation, the first multiplexer 313-1 may receive the first test meta data MD1 loaded onto the meta input and output line MIO from the meta storage circuit 270 and output the first test meta data MD1 as the first selection data SD1 under the control of the swap control circuit 12.

The first read pipe circuit 313-2 may receive the first selection data SD1 from the first multiplexer 313-1 under the control of the swap control circuit 12. The first read pipe circuit 313-2 may generate first latch data LD1 by latching the received first selection data SD1. The first read pipe circuit 313-2 may output the first latch data LD1 to the first serial conversion circuit 313-3. In the third mode of the training operation, the first read pipe circuit 313-2 may receive the first write data WD1 stored in the first write pipe circuit 312-3 under the control of the swap control circuit 12. The first read pipe circuit 313-2 may generate the first latch data LD1 by latching the received first write data WD1. In the third mode of the training operation, the first read pipe circuit 313-2 may output the first latch data LD1 to the first serial conversion circuit 313-3.

The first serial conversion circuit 313-3 may convert the first latch data LD1 that are input in parallel through the first read pipe circuit 313-2 in series. The first serial conversion circuit 313-3 may generate the first read data RD1 from the first latch data LD1 that have been converted in series, and may output the first read data RD1 to the first transmitter 313-4.

The first transmitter 313-4 may receive the first read data RD1 through the first serial conversion circuit 313-3 in synchronization with a rising edge and falling edge of the write clock WCK. The first transmitter 313-4 may output the first read data RD1 received in synchronization with a rising edge and falling edge of the write clock WCK to the first pad 311.

Only data that are input to and output from each of the second to tenth data transfer circuits 231-2 to 231-10 illustrated in FIG. 3 are different from the data that are input to and output from the first data transfer circuit 231-1 illustrated in FIG. 4. Each of the second to tenth data transfer circuits 231-2 to 231-10 is implemented with the same circuit as the first data transfer circuit 231-1 and performs the same operation as the first data transfer circuit 231-1, and thus a detailed description thereof is omitted.

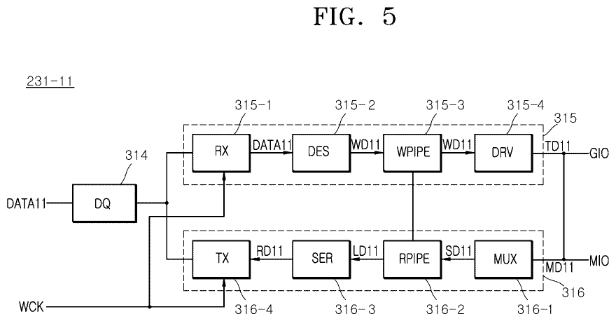

FIG. 5 is a block diagram illustrating a construction of the eleventh data transfer circuit 231-11 included in the data input and output circuit 230 illustrated in FIG. 3 according to an embodiment of the present disclosure. The eleventh data transfer circuit 231-11 may include an eleventh pad (DQ) 314, an eleventh write transfer circuit 315, and an eleventh read transfer circuit 316.

After the start of write operations of the normal operation and the training operation, the eleventh pad 314 may receive the eleventh data DATA11 and output the eleventh data DATA11 to the eleventh write transfer circuit 315. After the start of read operations of the normal operation and the training operation, the eleventh pad 314 may receive eleventh read data RD11 from the eleventh read transfer circuit 316 and output the eleventh read data RD11 as the eleventh data DATA11.

The eleventh write transfer circuit 315 may include an eleventh receiver (RX) 315-1, an eleventh parallel conversion circuit (DES) 315-2, an eleventh write pipe circuit (WPIPE) 315-3, an eleventh driver (DRV) 315-4.

The eleventh receiver 315-1 may receive the eleventh data DATA11 through the eleventh pad 314 in synchronization with a rising edge and falling edge of the write clock WCK. The eleventh receiver 315-1 may output the received eleventh data DATA11 to the eleventh parallel conversion circuit 315-2 in synchronization with a rising edge and falling edge of the write clock WCK.

The eleventh parallel conversion circuit 315-2 may convert the eleventh data DATA11 that are input in series through the eleventh receiver 315-1 in parallel. The eleventh parallel conversion circuit 315-2 may generate eleventh write data WD11 from the eleventh data DATA11 that have been converted in parallel, and may output the eleventh write data WD11 to the eleventh write pipe circuit 315-3.

The eleventh write pipe circuit 315-3 may latch the eleventh write data WD11 that have been converted in parallel. The eleventh write pipe circuit 315-3 may output the latched eleventh write data WD11 to the eleventh driver 315-4. In the third mode of the training operation, the eleventh write pipe circuit 315-3 may output the eleventh write data WD11 stored in the eleventh write pipe circuit 315-3 to an eleventh read pipe circuit (RPIPE) 316-2 under the control of the swap control circuit 12.

The eleventh driver 315-4 may generate the eleventh transfer data TD11 based on the eleventh write data WD11. The eleventh driver 315-4 may output the eleventh transfer data TD11 to the plurality of data input and output lines GIO and the plurality of meta input and output lines MIO. The eleventh driver 315-4 may output the eleventh transfer data TD11 to the plurality of data input and output lines GIO and the plurality of meta input and output lines MIO by driving the plurality of data input and output lines GIO and the plurality of meta input and output lines MIO based on the logic levels of bits included in the eleventh transfer data TD11. The eleventh driver 315-4 may output bits to be stored in the data storage circuit 260, among the eleventh write data WD11, to the plurality of data input and output lines GIO. The eleventh driver 315-4 may output bits to be stored in the meta storage circuit 270, among the eleventh write data WD11, to the plurality of meta input and output lines MIO.

The eleventh read transfer circuit 316 may include an eleventh multiplexer (MUX) 316-1, an eleventh read pipe circuit (RPIPE) 316-2, an eleventh serial conversion circuit (SER) 316-3, and an eleventh transmitter (TX) 316-4.

The eleventh multiplexer 316-1 may receive any one of the eleventh transfer data TD11 loaded onto the data input and output line GIO from the data storage circuit 260 and the eleventh test meta data MD11 loaded onto the meta input and output line MIO from the meta storage circuit 270, and may output any one of the eleventh transfer data TD1 and the eleventh test meta data MD11 as eleventh selection data SD11. In the first and second modes of the normal operation and the training operation, the eleventh multiplexer 316-1 may receive the eleventh transfer data TD11 loaded onto the data input and output line GIO from the data storage circuit 260 and output the eleventh transfer data TD1 as the eleventh selection data SD11 under the control of the swap control circuit 12. In the third mode of the training operation, the eleventh multiplexer 316-1 may receive the eleventh test meta data MD11 loaded onto the meta input and output line MIO from the meta storage circuit 270 and output the eleventh test meta data MD11 as the eleventh selection data SD11 under the control of the swap control circuit 12.

The eleventh read pipe circuit 316-2 may receive the eleventh selection data SD11 from the eleventh multiplexer 316-1 under the control of the swap control circuit 12. The eleventh read pipe circuit 316-2 may generate eleventh latch data LD11 by latching the received eleventh selection data SD11. The eleventh read pipe circuit 316-2 may output the eleventh latch data LD11 to the eleventh serial conversion circuit 316-3. In the third mode of the training operation, the eleventh read pipe circuit 316-2 may receive the eleventh write data WD11 stored in the eleventh write pipe circuit 315-3 under the control of the swap control circuit 12. The eleventh read pipe circuit 316-2 may generate the eleventh latch data LD11 by latching the received eleventh write data WD11. In the third mode of the training operation, the eleventh read pipe circuit 316-2 may output the eleventh latch data LD11 to the eleventh serial conversion circuit 316-3.

The eleventh serial conversion circuit 316-3 may convert the eleventh latch data LD11 that are input in parallel through the eleventh read pipe circuit 316-2 in series. The eleventh serial conversion circuit 316-3 may generate the eleventh read data RD11 from the eleventh latch data LD11 that have been converted in series, and may output the eleventh read data RD11 to the eleventh transmitter 316-4.

The eleventh transmitter 316-4 may receive the eleventh read data RD11 through the eleventh serial conversion circuit 316-3 in synchronization with a rising edge and falling edge of the write clock WCK. The eleventh transmitter 316-4 may output the eleventh read data RD11 received in synchronization with a rising edge and falling edge of the write clock WCK to the eleventh pad 314.

Only data that are input to and output from the twelfth data transfer circuit 231-12 illustrated in FIG. 3 are different from the data that are input to and output from the eleventh data transfer circuit 231-11 illustrated in FIG. 5. The twelfth data transfer circuit 231-12 is implemented with the same circuit as the eleventh data transfer circuit 231-11 and performs the same operation as the eleventh data transfer circuit 231-11, and thus a detailed description thereof is omitted.

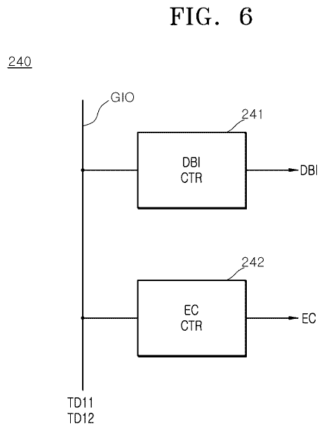

FIG. 6 is a block diagram illustrating a construction of the data control circuit 240 included in the memory device 20 illustrated in FIG. 2, according to an embodiment of the present disclosure. The data control circuit 240 may include a data inversion control circuit (DBI CTR) 241 and an error correction control circuit (EC CTR) 242.

After the start of the normal operation, the data inversion control circuit 241 may generate the data inversion signal DBI based on data inversion information that is included in bits included in the eleventh transfer data TD11 and bits included in the twelfth transfer data TD12, which are loaded onto the data input and output line GIO. The data inversion control circuit 241 may generate the data inversion signal DBI at a logic high level, which is generated when the data inversion information that is generated when the number of logic high levels, among bits included in the first to tenth data DATA1 to DATA10, is greater than ½ is input.

After the start of the normal operation, the error correction control circuit 242 may generate the error correction signal EC based on error information that is included in bits included in the eleventh transfer data TD11 and bits included in the twelfth transfer data TD12, which are loaded onto the data input and output line GIO. The error correction control circuit 242 may generate the plurality of error correction signals EC each including a bit at a logic high level, which corresponds to a bit including an error, based on error information that is generated when an error occurs in a bit included in the first to tenth data DATA1 to DATA10.

FIG. 7 is a block diagram illustrating a construction of the data storage circuit 260 included in the memory device 20 illustrated in FIG. 2, according to an embodiment of the present disclosure. The data storage circuit 260 may include the first to sixteenth banks 261-1 to 261-16.

The first bank 261-1 may include a memory cell region MC and a parity cell region PC. When the write signal WT is generated and the first bit BAD<1> of the bank address is generated, the first bank 261-1 may store the internal data ID loaded onto the internal input and output line INIO in the memory cell region MC based on the first to sixty-fourth bits CAD<1:64> of the column address. When the read signal RD is generated and the first bit BAD<1> of the bank address is generated, the first bank 261-1 may output the internal data ID stored in the memory cell region MC to the internal input and output line INIO based on the first to sixty-fourth bits CAD<1:64> of the column address. When the meta write signal MWT is generated and the first bit BAD<1> of the bank address is generated, the first bank 261-1 may output the internal data ID stored in the parity cell region PC to the internal input and output line INIO based on the first to sixty-fourth bits CAD<1:64> of the column address. When the meta read signal MRD is generated and the first bit BAD<1> of the bank address is generated, the first bank 261-1 may store the internal data ID loaded onto the internal input and output line INIO in the parity cell region PC based on the first to sixty-fourth bits CAD<1:64> of the column address.

The second bank 261-2 may include a memory cell region MC and a parity cell region PC. When the write signal WT is generated and the second bit BAD<2> of the bank address is generated, the second bank 261-2 may store the internal data ID loaded onto the internal input and output line INIO in the memory cell region MC based on the first to sixty-fourth bits CAD<1:64> of the column address. When the read signal RD is generated and the second bit BAD<2> of the bank address is generated, the second bank 261-2 may output the internal data ID stored in the memory cell region MC to the internal input and output line INIO based on the first to sixty-fourth bits CAD<1:64> of the column address. When the meta write signal MWT is generated and the second bit BAD<2> of the bank address is generated, the second bank 261-2 may output the internal data ID stored in the parity cell region PC to the internal input and output line INIO based on the first to sixty-fourth bits CAD<1:64> of the column address. When the meta read signal MRD is generated and the second bit BAD<2> of the bank address is generated, the second bank 261-2 may store the internal data ID loaded onto the internal input and output line INIO in the parity cell region PC based on the first to sixty-fourth bits CAD<1:64> of the column address.

Each of the third to sixteenth banks 261-3 to 261-16 is merely selected when each of the third to sixteenth bits BAD<3:16> of the bank address is generated, and is implemented with the same circuit as each of the first and second banks 261-1 and 261-2 and performs the same operation as each of the first and second banks 261-1 and 261-2, and thus a detailed description thereof is omitted.

Each of the first to sixteenth banks 261-1 to 261-16 may input and output the internal data ID of 256 bits after the start of a single write operation and read operation.

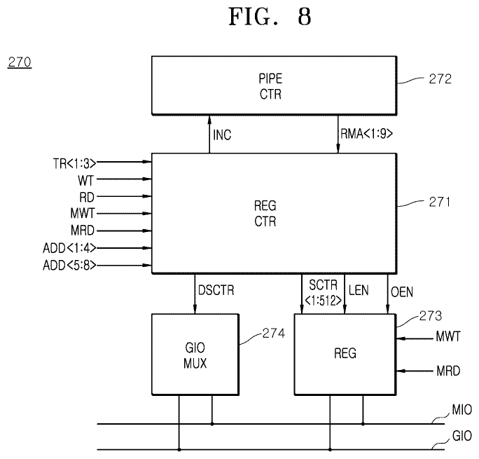

FIG. 8 is a block diagram illustrating a construction of the meta storage circuit 270 included in the memory device 20 illustrated in FIG. 2, according to an embodiment of the present disclosure. The meta storage circuit 270 may include a register control circuit (REG CTR) 271, a pipe control circuit (PIPE CTR) 272, a register circuit (REG) 273, and an input and output line selection circuit (GIO MUX) 274.

The register control circuit 271 may generate a counting pulse INC, first to 512-th bits SCTR<1:512> of a storage control signal, a latch enable signal LEN, an output enable signal OEN, and a data selection signal DSCTR, based on the first to third bits TR<1:3> of the training signal, the write signal WT, the read signal RD, the meta write signal MWT, the meta read signal MRD, the first to eighth bits ADD<1:8> of the address, and first to ninth bits RMA<1:9> of a counting address.

The register control circuit 271 may generate the counting pulse INC that is generated whenever the second and third bits TR<2:3> of the training signal are generated and the write signal WT is generated. The register control circuit 271 may generate the counting pulse INC that is generated whenever the second and third bits TR<2:3> of the training signal are generated and the read signal RD is generated.

The register control circuit 271 may generate the first to 512-th bits SCTR<1:512> of the storage control signal that are selectively generated based on the first to fourth bits ADD<1:4> of the address and the fifth to eighth bits ADD<5:8> of the address when the first to third bits TR<1:3> of the training signal are not generated.

The register control circuit 271 may generate the first to 512-th bits SCTR<1:512> of the storage control signal that are selectively generated based on the first to fourth bits ADD<1:4> of the address and the fifth to seventh bits ADD<5:7> of the address when the first bit TR<1> of the training signal is generated.

The register control circuit 271 may generate the counting pulse INC that is generated whenever the write signal WT and the read signal RD are input when the second bit TR<2> of the training signal and the third bit TR<3> of the training signal are generated. The register control circuit 271 may generate the first to 512-th bits SCTR<1:512> of the storage control signal that are sequentially generated based on the first to ninth bits RMA<1:9> of the counting address when the second bit TR<2> of the training signal and the third bit TR<3> of the training signal are generated.

The register control circuit 271 may generate the latch enable signal LEN that is generated when the write signal WT and the meta write signal MWT are input. The register control circuit 271 may generate the output enable signal OEN that is generated when the read signal RD and the meta read signal MRD are input.

The register control circuit 271 may generate the data selection signal DSCTR that is generated when the third bit TR<3> of the training signal is generated and the write signal WT are input.

The pipe control circuit 272 may generate the first to ninth bits RMA<1:9> of the counting address that are sequentially up-counted whenever the counting pulse INC is input.

The register circuit 273 may include a plurality of registers. When the plurality of registers is selected by the first to 512-th bits SCTR<1:512> of the storage control signal and the meta write signal MWT and the latch enable signal LEN are generated, the register circuit 273 may store the eleventh and twelfth transfer data TD11 and TD12 loaded onto the data input and output line GIO in a selected register. When the plurality of registers is selected by the first to 512-th bits SCTR<1:512> of the storage control signal and the meta read signal MRD and the output enable signal OEN are generated, the register circuit 273 may output the eleventh and twelfth transfer data TD11 and TD12 stored in a selected register to the data input and output line GIO. When the plurality of registers is selected by the first to 512-th bits SCTR<1:512> of the storage control signal and the latch enable signal LEN is generated, the register circuit 273 may store the eleventh and twelfth transfer data TD11 and TD12, which are loaded onto the meta input and output line MIO, in a selected register. When the plurality of registers is selected by the first to 512-th bits SCTR<1:512> of the storage control signal and the output enable signal OEN is generated, the register circuit 273 may output the eleventh and twelfth transfer data TD11 and TD12 stored in a selected register to the meta input and output line MIO.

When the data selection signal DSCTR is generated, the input and output line selection circuit 274 may output any one of the first to tenth transfer data loaded onto the data input and output line GIO to the meta input and output line MIO.

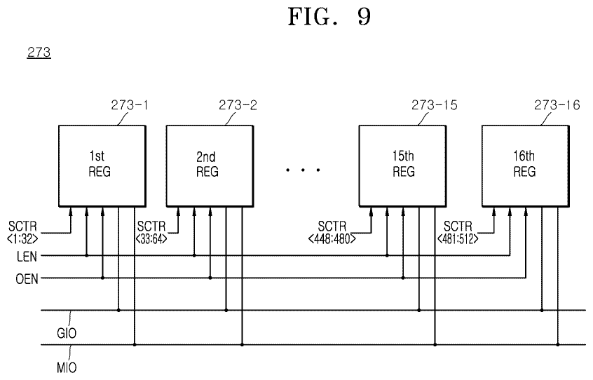

FIG. 9 is a block diagram illustrating a construction according to an embodiment of the register circuit 273 included in the meta storage circuit 270 illustrated in FIG. 8 according to an embodiment of the present disclosure. The register circuit 273 may include the first to sixteenth register circuits (1^{st} REG to 16^{th} REG) 273-1 to 273-16.

The first register circuit 273-1 may include 32 registers (8 bit STG) (310-1 to 310-32 in FIG. 10). When the 32 registers (310-1 to 310-32 in FIG. 10) are selected by the first to thirty-second bits SCTR<1:32> of the storage control signal and the meta write signal MWT and the latch enable signal LEN are generated, the first register circuit 273-1 may store the eleventh and twelfth transfer data TD11 and TD12 loaded onto the data input and output line GIO in a selected register. When the 32 registers (310-1 to 310-32 in FIG. 10) are selected by the first to thirty-second bits SCTR<1:32> of the storage control signal and the meta read signal MRD and the output enable signal OEN are generated, the first register circuit 273-1 may output the eleventh and twelfth transfer data TD11 and TD12 stored in a selected register to the data input and output line GIO. When the 32 registers (310-1 to 310-32 in FIG. 10) are selected by the first to thirty-second bits SCTR<1:32> of the storage control signal and the latch enable signal LEN is generated, the first register circuit 273-1 may store the eleventh and twelfth transfer data TD11 and TD12, which are loaded onto the meta input and output line MIO, in a selected register. When the 32 registers (310-1 to 310-32 in FIG. 10) are selected by the first to thirty-second bits SCTR<1:32> of the storage control signal and the output enable signal OEN is generated, the first register circuit 273-1 may output the eleventh and twelfth transfer data TD11 and TD12 stored in a selected register to the meta input and output line MIO.

The second register circuit 273-2 may include 32 registers (not illustrated). When the 32 registers (not illustrated) are selected by the thirty-third to sixty-fourth bits SCTR<33:64> of the storage control signal and the meta write signal MWT and the latch enable signal LEN are generated, the second register circuit 273-2 may store the eleventh and twelfth transfer data TD11 and TD12 loaded onto the data input and output line GIO in a selected register. When the 32 registers (not illustrated) are selected by the thirty-third to sixty-fourth bits SCTR<33:64> of the storage control signal and the meta read signal MRD and the output enable signal OEN are generated, the second register circuit 273-2 may output the eleventh and twelfth transfer data TD11 and TD12 stored in a selected register to the data input and output line GIO. When the 32 registers (not illustrated) are selected by the thirty-third to sixty-fourth bits SCTR<33:64> of the storage control signal and the latch enable signal LEN is generated, the second register circuit 273-2 may store the eleventh and twelfth transfer data TD11 and TD12, which are loaded onto the meta input and output line MIO, in a selected registers. When the 32 registers (not illustrated) are selected by the thirty-third to sixty-fourth bits SCTR<33:64> of the storage control signal and the output enable signal OEN is generated, the second register circuit 273-2 may output the eleventh and twelfth transfer data TD11 and TD12 stored in a selected registers to the meta input and output line MIO.

The fifteenth register circuit 273-15 may include 32 registers (not illustrated). When the 32 registers (not illustrated) are selected by the 448-th to 480-th bits SCTR<448:480> of the storage control signal and the meta write signal MWT and the latch enable signal LEN are generated, the fifteenth register circuit 273-15 may store the eleventh and twelfth transfer data TD11 and TD12 loaded onto the data input and output line GIO in a selected register. When the 32 registers (not illustrated) are selected by the 448-th to 480-th bits SCTR<448:480> of the storage control signal and the meta read signal MRD and the output enable signal OEN are generated, the fifteenth register circuit 273-15 may output the eleventh and twelfth transfer data TD11 and TD12 stored in a selected register to the data input and output line GIO. When the 32 registers (not illustrated) are selected by the 448-th to 480-th bits SCTR<448:480> of the storage control signal and the latch enable signal LEN is generated, the fifteenth register circuit 273-15 may store the eleventh and twelfth transfer data TD11 and TD12, which are loaded onto the meta input and output line MIO, in a selected register. When the 32 registers (not illustrated) are selected by the 448-th to 480-th bits SCTR<448:480> of the storage control signal and the output enable signal OEN is generated, the fifteenth register circuit 273-15 may output the eleventh and twelfth transfer data TD11 and TD12 stored in a selected register to the meta input and output line MIO.

The sixteenth register circuit 273-16 may include 32 registers (not illustrated). When the 32 registers (not illustrated) are selected by the 481-th to 512-th bits SCTR<481:512> of the storage control signal and the meta write signal MWT and the latch enable signal LEN are generated, the sixteenth register circuit 273-16 may store the eleventh and twelfth transfer data TD11 and TD12 loaded onto the data input and output line GIO in a selected register. When the 32 registers (not illustrated) are selected by the 481-th to 512-th bits SCTR<481:512> of the storage control signal and the meta read signal MRD and the output enable signal OEN are generated, the sixteenth register circuit 273-16 may output the eleventh and twelfth transfer data TD11 and TD12 stored in a selected register to the data input and output line GIO. When the 32 registers (not illustrated) are selected by the 481-th to 512-th bits SCTR<481:512> of the storage control signal and the latch enable signal LEN is generated, the sixteenth register circuit 273-16 may store the eleventh and twelfth transfer data TD11 and TD12, which are loaded onto the meta input and output line MIO, in a selected register. When the 32 registers (not illustrated) are selected by the 481-th to 512-th bits SCTR<481:512> of the storage control signal and the output enable signal OEN is generated, the sixteenth register circuit 273-16 may output the eleventh and twelfth transfer data TD11 and TD12 stored in a selected registers to the meta input and output line MIO.

Only bits of the storage control signal that are input to each of the third to fourteenth register circuits 273-3 to 273-14 are different from the bits that are input to each of the first register circuit 273-1, the second register circuit 273-2, the fifteenth register circuit 273-15, and the sixteenth register circuit 273-16. Each of the third to fourteenth register circuits 273-3 to 273-14 is implemented with the same circuit as each of the first register circuit 273-1, the second register circuit 273-2, the fifteenth register circuit 273-15, and the sixteenth register circuit 273-16 and performs the same operation as each of the first register circuit 273-1, the second register circuit 273-2, the fifteenth register circuit 273-15, and the sixteenth register circuit 273-16, and thus a detailed description thereof is omitted.

FIG. 10 is a block diagram illustrating a construction of the first register circuit 273-1 included in the register circuit 273 illustrated in FIG. 9, according to an embodiment of the present disclosure. The first register circuit 273-1 may include the first to thirty-second registers (8 bit STG) 310-1 to 310-32.

The first register 310-1 may be selected when the first bit SCTR<1> of the storage control signal is generated. When the first bit SCTR<1> of the storage control signal is generated and the meta write signal MWT and the latch enable signal LEN are generated, the first register 310-1 may store the eleventh and twelfth transfer data TD11 and TD12 loaded onto the data input and output line GIO. When the first bit SCTR<1> of the storage control signal is generated and the meta read signal MRD and the latch enable signal LEN are generated, the first register 310-1 may output the stored eleventh and twelfth transfer data TD11 and TD12 to the data input and output line GIO. When the first bit SCTR<1> of the storage control signal is generated, the meta write signal MWT is not generated, and the latch enable signal LEN is generated, the first register 310-1 may store the eleventh and twelfth transfer data TD11 and TD12 loaded onto the meta input and output line MIO. When the first bit SCTR<1> of the storage control signal is generated, the meta read signal MRD is not generated, and the output enable signal OEN is generated, the first register 310-1 may output the stored eleventh and twelfth transfer data TD11 and TD12 to the meta input and output line MIO. The first register 310-1 may be connected to eight meta input and output lines MIO, among the plurality of meta input and output lines MIO, and may input and output the eleventh and twelfth transfer data TD11 and TD12 of 8 bits.

The second register 310-2 may be selected when the second bit SCTR<2> of the storage control signal is generated. When the second bit SCTR<2> of the storage control signal is generated and the meta write signal MWT and the latch enable signal LEN are generated, the second register 310-2 may store the eleventh and twelfth transfer data TD11 and TD12 loaded onto the data input and output line GIO. When the second bit SCTR<2> of the storage control signal is generated and the meta read signal MRD and the latch enable signal LEN are generated, the second register 310-2 may output the eleventh and twelfth transfer data TD11 and TD12, which are stored in the second register 310-2, to the data input and output line GIO. When the second bit SCTR<2> of the storage control signal is generated, the meta write signal MWT is not generated, and the latch enable signal LEN is generated, the second register 310-2 may store the eleventh and twelfth transfer data TD11 and TD12 loaded onto the meta input and output line MIO. When the second bit SCTR<2> of the storage control signal is generated, the meta read signal MRD is not generated, and the output enable signal OEN is generated, the second register 310-2 may output the eleventh and twelfth transfer data TD11 and TD12, which are stored in the second register 310-2, to the meta input and output line MIO. The second register 310-2 may be connected to eight meta input and output lines MIO, among the plurality of meta input and output lines MIO, and may input and output the eleventh and twelfth transfer data TD11 and TD12 of 8 bits.

Only bits of the storage control signal that are input to each of the third to thirty-second registers 310-3 to 310-32 are different from the bits that are input to each of the first and second registers 310-1 and 310-2 illustrated in FIG. 9. Each of the third to thirty-second registers 310-3 to 310-32 is implemented with the same circuit as each of the first and second registers 310-1 and 310-2 and performs the same operation as each of the first and second registers 310-1 and 310-2, and thus a detailed description thereof is omitted. Each of the third to thirty-second registers 310-3 to 310-32 may be connected to eight meta input and output lines MIO, among the plurality of meta input and output lines MIO, and may input and output the eleventh and twelfth transfer data TD11 and TD12 of 8 bits.

The first register circuit 273-1 illustrated in FIG. 10 may be implemented with 32 registers to input and output data including the same number of 256 bits as data that are input to and output from the first bank 261-1.

Each of the second to sixteenth register circuits 273-2 to 273-16 illustrated in FIG. 9 is implemented with the same circuit as the first register circuit 273-1 and performs the same operation as the first register circuit 273-1, and thus a detailed description thereof is omitted.

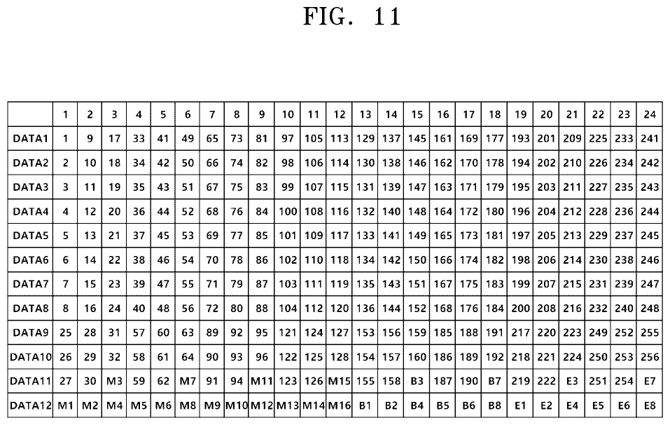

FIG. 11 is a diagram of a data map for describing data according to an embodiment of the present disclosure.

The first to twelfth data DATA1 to DATA12 may be input and output to include 256 bits used for data, 16 bits used for error information, 8 bits used for data inversion information, and 8 bits used for link error information.

The first data DATA1 used for data may be input and output with 24 bits.

The first data DATA1 may be input and output to include a first bit 1, a ninth bit 9, a seventeenth bit 17, thirty-third bit 33, a forty-first bit 41, a forty-ninth bit 49, a sixty-fifth bit 65, a seventy-third bit 73, an eighty-first bit 81, a ninety-seventh bit 97, a 105-th bit 105, a 113-th bit 113, a 129-th bit 129, a 137-th bit 137, a 145-th bit 145, a 161-th bit 161, a 169-th bit 169, a 177-th bit 177, a 193-th bit 193, a 201-th bit 201, a 209-th bit 209, a 225-th bit 225, a 233-th bit 233, and a 241-th bit 241, among the 256 bits that are used for data.

Each of the second to tenth data DATA2 to DATA10 may be input and output to include 24 bits used for data like the first data DATA1.

The eleventh data DATA11 may be input and output to include a twenty-seventh bit 27, a thirtieth bit 30, a fifty-ninth bit 59, a sixty-second bit 62, a ninety-first bit 91, a ninety-fourth bit 94, a 123-th bit 123, a 126-th bit 126, a 155-th bit 155, a 158-th bit 158, a 187-th bit 187, a 190-th bit 190, a 219-th bit 219, a 222-th bit 222, a 251-th bit 251, and a 254-th bit 254, among the 256 bits that are used for data.

The eleventh data DATA11 may be input and output to include a third bit M3, a seventh bit M7, an eleventh bit M11, and a fifteenth bit M15, among the 16 bits that are used for error information.

The eleventh data DATA11 may be input and output to include a third bit B3 and a seventh bit B7, among the 8 bits that are used for data inversion information.

The eleventh data DATA11 may be input and output to include a third bit E3 and a seventh bit E7, among the 8 bits that are used for link error information.

The twelfth data DATA12 may be input and output to include a first bit M1, a second bit M2, a fourth bit M4, a fifth bit M5, a sixth bit M6, an eighth bit M8, a ninth bit M9, a tenth bit M10, a twelfth bit M12, a thirteenth bit M13, a fourteenth bit M14, and a sixteenth bit M16, among the 16 bits that are used for error information.

The twelfth data DATA12 may be input and output to include a first bit B1, a second bit B2, a fourth bit B4, a fifth bit B5, a sixth bit B6, and an eighth bit B8, among the 8 bits that are used for data inversion information.

The twelfth data DATA12 may be input and output to include a first bit E1, a second bit E2, a fourth bit E4, a fifth bit E5, a sixth bit E6, and an eighth bit E8, among the 8 bits that are used for link error information.

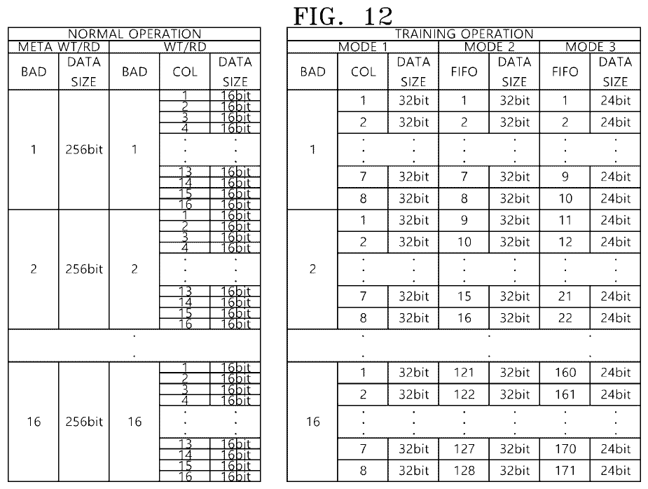

FIG. 12 is a diagram for describing data that are input and output based on the address according to an embodiment of the present disclosure.

First, the number of bits of data (DATA SIZE) that are input and output by the address in a meta write operation META WT and meta read operation META RD of the normal operation is described as follows.

In the meta write operation META WT of the normal operation, when the first bit BAD<1> of the bank address is generated, the first bank 261-1 may store the internal data ID of 256 bits, which are loaded onto the internal input and output line INIO, in the parity cell region PC. In the meta read operation META RD of the normal operation, when the first bit BAD<1> of the bank address is generated, the first bank 261-1 may output the internal data ID of 256 bits, which are stored in the parity cell region PC, to the internal input and output line INIO.

In the meta write operation META WT of the normal operation, when the second bit BAD<2> of the bank address is generated, the second bank 261-2 may store the internal data ID of 256 bits, which are loaded onto the internal input and output line INIO, in the parity cell region PC. In the meta read operation META RD of the normal operation, when the second bit BAD<2> of the bank address is generated, the second bank 261-2 may output the internal data ID of 256 bits, which are stored in the parity cell region PC, to the internal input and output line INIO.

In the meta write operation META WT and meta read operation META RD of the normal operation, each of the third to sixteenth banks 261-3 to 261-16 performs the same operation as each of the first and second banks 261-1 and 261-2, and thus a detailed description thereof is omitted.

In the meta write operation META WT and meta read operation META RD of the normal operation, the first to sixteenth banks 261-1 to 261-16 may input and output the internal data ID of 4,096 bits (4 kilobits) by each inputting and outputting the internal data ID of 256 bits.

Next, the number of bits of data (DATA SIZE) that are input and output by the address in a write operation WT and read operation RD of the normal operation is described as follows.

In the write operation WT of the normal operation, when the first bit BAD<1> of the bank address is generated, the memory cell region MC of the first bank 261-1 may store the internal data ID of 16 bits, which are loaded onto the internal input and output line INIO, through one column operation COL. In the read operation RD of the normal operation, when the first bit BAD<1> of the bank address is generated, the memory cell region MC of the first bank 261-1 may output the internal data ID of 16 bits, which are stored in the memory cell region MC, to the internal input and output line INIO through one column operation COL. The first bank 261-1 may input and output the internal data ID of 256 bits by inputting and outputting the internal data ID of 16 bits 16 times through sixteen column operations COL.

In the write operation WT of the normal operation, when the second bit BAD<2> of the bank address is generated, the memory cell region MC of the second bank 261-2 may store the internal data ID of 16 bits, which are loaded onto the internal input and output line INIO, through one column operation COL. In the read operation RD of the normal operation, when the second bit BAD<2> of the bank address is generated, the memory cell region MC of the second bank 261-2 may output the internal data ID of 16 bits, which are stored in the memory cell region MC, to the internal input and output line INIO through one column operation COL. The second bank 261-2 may input and output the internal data ID of 256 bits by inputting and outputting the internal data ID of 16 bits 16 times through sixteen column operations COL.

In the write operation WT and read operation RD of the normal operation, each of the third to sixteenth banks 261-3 to 261-16 performs the same operation as each of the first and second banks 261-1 and 261-2, and thus a detailed description thereof is omitted.

In the write operation WT and read operation RD of the normal operation, the first to sixteenth banks 261-1 to 261-16 may input and output the internal data ID of 4,096 bits (4 kilobits) by each inputting and outputting the internal data ID of 256 bits.

Next, the number of bits of data (DATA SIZE) that are input and output by the address in the first mode MODE1 of the training operation is described as follows.

In the first mode MODE1 of the training operation, after the start of a write operation, when the first bit BAD<1> of the bank address is generated, the first register circuit 273-1 may store the eleventh and twelfth transfer data TD11 and TD12 of 32 bits, which are loaded onto the meta input and output line MIO, through one column operation COL. In the first mode MODE1 of the training operation, after the start of a read operation, when the first bit BAD<1> of the bank address is generated, the first register circuit 273-1 may output the eleventh and twelfth transfer data TD11 and TD12 of 32 bits, which are stored in the first register circuit 273-1, to the meta input and output line MIO through one column operation COL. The first register circuit 273-1 may input and output the eleventh and twelfth transfer data TD11 and TD12 of 256 bits by inputting and outputting the eleventh and twelfth transfer data TD11 and TD12 of 32 bits eight times through eight column operations COL.

In the first mode MODE1 of the training operation, after the start of a write operation, when the second bit BAD<2> of the bank address is generated, the second register circuit 273-2 may store the eleventh and twelfth transfer data TD11 and TD12 of 32 bits, which are loaded onto the meta input and output line MIO, through one column operation COL. In the first mode MODE1 of the training operation, after the start of a read operation, when the second bit BAD<2> of the bank address is generated, the second register circuit 273-2 may output the eleventh and twelfth transfer data TD11 and TD12 of 32 bits, which are stored in the second register circuit 273-2, to the meta input and output line MIO through one column operation COL. The second register circuit 273-2 may input and output the eleventh and twelfth transfer data TD11 and TD12 of 256 bits by inputting and outputting the eleventh and twelfth transfer data TD11 and TD12 of 32 bits eight times through eight column operations COL.

Each of the third to sixteenth register circuits 273-3 to 273-16 performs the same operation as each of the first and second register circuits 273-1 and 273-2 after the start of a write operation and a read operation in the first mode of the training operation, and thus a detailed description thereof is omitted.

In the first mode of the training operation, after the start of a write operation and a read operation, the first to sixteenth register circuits 273-1 to 273-16 may input and output the eleventh and twelfth transfer data TD11 and TD12 of 4,096 bits (4 kilobits) by each inputting and outputting the eleventh and twelfth transfer data TD11 and TD12 of 256 bits.

Next, the number of bits of data (DATA SIZE) that are input and output (first in first output (FIFO)) by the plurality of registers that is included in the register circuit and that is sequentially selected regardless of the address in the second mode MODE2 of the training operation is described as follows.

In the second mode MODE2 of the training operation, after the start of a write operation, registers included in the first register circuit 273-1 may be sequentially selected regardless of the address, and may store the eleventh and twelfth transfer data TD11 and TD12 of 32 bits, which are loaded onto the meta input and output line MIO, through one column operation COL. In the second mode MODE2 of the training operation, after the start of a read operation, the registers included in the first register circuit 273-1 may be sequentially selected regardless of the address, and may output the eleventh and twelfth transfer data TD11 and TD12 of 32 bits, which are stored in the registers, to the meta input and output line MIO through one column operation COL. The first register circuit 273-1 may input and output the eleventh and twelfth transfer data TD11 and TD12 of 256 bits by inputting and outputting the eleventh and twelfth transfer data TD11 and TD12 of 32 bits eight times through eight column operations COL.

In the second mode MODE2 of the training operation, after the start of a write operation, registers included in the second register circuit 273-2 may be sequentially selected regardless of the address, and may store the eleventh and twelfth transfer data TD11 and TD12 of 32 bits, which are loaded onto the meta input and output line MIO, through one column operation COL. In the second mode MODE2 of the training operation, after the start of a read operation, the registers included in the second register circuit 273-2 may be sequentially selected regardless of the address, and may output the eleventh and twelfth transfer data TD11 and TD12 of 32 bits, which are stored in the registers, to the meta input and output line MIO through one column operation COL. The second register circuit 273-2 may input and output the eleventh and twelfth transfer data TD11 and TD12 of 256 bits by inputting and outputting the eleventh and twelfth transfer data TD11 and TD12 of 32 bits eight times through eight column operations COL.

In the second mode of the training operation, after the start of a write operation and a read operation, each of the third to sixteenth register circuits 273-3 to 273-16 performs the same operation as each of the first and second register circuits 273-1 and 273-2, and thus a detailed description thereof is omitted.

In the second mode of the training operation, after the start of a write operation and a read operation, the first to sixteenth register circuits 273-1 to 273-16 may input and output the eleventh and twelfth transfer data TD11 and TD12 of 4,096 bits (4 kilobits) by each inputting and outputting the eleventh and twelfth transfer data TD11 and TD12 of 256 bits.

Next, the number of bits of data (DATA SIZE) that are input and output (FIFO) by the plurality of registers that are included in the register circuit and are sequentially selected regardless of the address in the third mode MODE3 of the training operation is described as follows.

In the third mode MODE3 of the training operation, after the start of a write operation, registers included in the first to sixteenth register circuits 273-1 to 273-16 may be sequentially selected regardless of the address, and may store any one of the first to tenth data DATA1 to DATA10 including 24 bits, which are loaded onto the data input and output line GIO, through one column operation COL. In the third mode MODE3 of the training operation, after the start of a read operation, the registers included in the first to sixteenth register circuits 273-1 to 273-16 may be sequentially selected regardless of the address, and may output any one of the first to tenth data DATA1 to DATA10 including 24 bits, which has been stored in the registers, to the meta input and output line MIO through one column operation COL.

The first to sixteenth register circuits 273-1 to 273-16 may input and output, through 171 column operations COL, any one of the first to tenth data DATA1 to DATA10 of 4,096 bits (4 kilobits) by inputting and outputting, 171 number of times, any one of the first to tenth data DATA1 to DATA10 each including 24 bits.

As described above, after the start of the training operation, the semiconductor system 1 according to an embodiment of the present disclosure may learn data and the data clock, with data having a long pattern by using a plurality of memory cells and a plurality of registers. After the start of the training operation, the semiconductor system 1 may learn data and the data clock, that input and output error information with data having a long pattern by using the meta storage circuit that inputs and outputs error information.

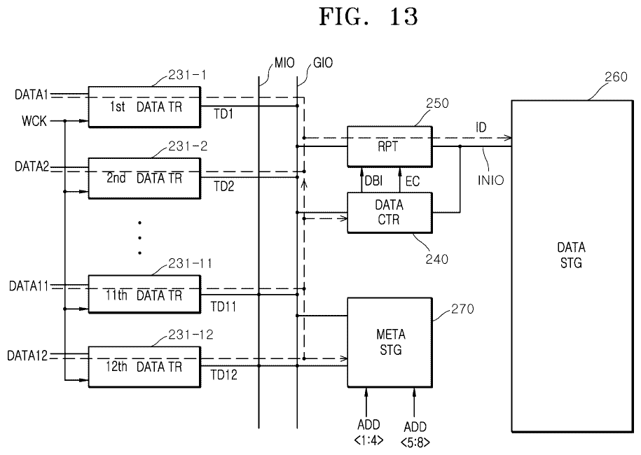

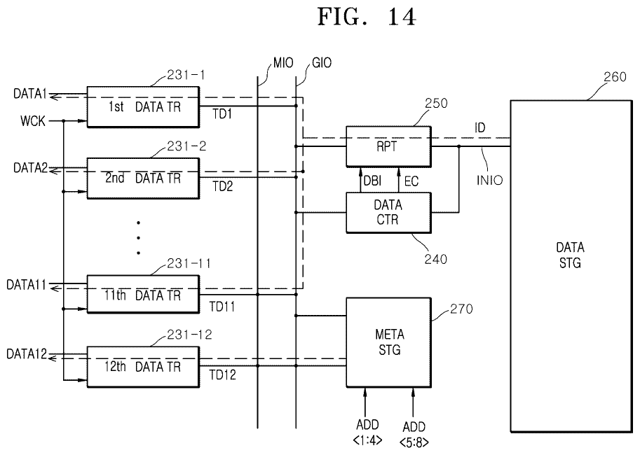

FIGS. 13 and 14 are diagrams for describing the normal operation according to an embodiment of the present disclosure.

The normal operation according to an embodiment of the present disclosure is described with reference to FIG. 13. In this case, a write operation through the data input and output circuit 230, the data storage circuit 260, and the meta storage circuit 270 is described as follows.

The command decoding circuit 210 generates the write signal WT by decoding the first to L-th bits CMD<1:L> of the command.

The address decoding circuit 220 generates the first to sixteenth bits BAD<1:16> of the bank address and the first to sixty-fourth bits CAD<1:64> of the column address by decoding the first to tenth bits ADD<1:10> of the address.

After the start of the write operation of the normal operation, the first data transfer circuit 231-1 generates the first transfer data TD1 of 24 bits by receiving the first data DATA1 of 24 bits in synchronization with the data clock WCK, and outputs the first transfer data TD1 to the data input and output line GIO.

After the start of the write operation of the normal operation, the second to tenth data transfer circuits 231-2 to 231-10 generate the second to tenth transfer data TD2 to TD10 each including 24 bits, respectively, by receiving the second to tenth data DATA2 to DATA10 each including 24 bits, respectively, in synchronization with the data clock WCK, and outputs the second to tenth transfer data TD2 to TD10 to the data input and output line GIO.

After the start of the write operation of the normal operation, the eleventh data transfer circuit 231-11 generates the eleventh transfer data TD11 of 24 bits by receiving the eleventh data DATA11 of 24 bits in synchronization with the data clock WCK, and outputs the eleventh transfer data TD11 to the data input and output line GIO. In this case, 16 bits for data, 4 bits including data inversion information, and 4 bits including error information, among the eleventh transfer data TD11 of 24 bits, are output to the data input and output line GIO.

After the start of the write operation of the normal operation, the twelfth data transfer circuit 231-12 generates the twelfth transfer data TD12 of 24 bits by receiving the twelfth data DATA12 of 24 bits in synchronization with the data clock WCK, and outputs the twelfth transfer data TD12 to the data input and output line GIO and the meta input and output line MIO. In this case, 12 bits including data inversion information and 12 bits including error information, among the twelfth transfer data TD12 of 24 bits, are output to the meta input and output line MIO and the data input and output line GIO.

The data control circuit 240 generates the data inversion signal DBI based on data inversion information of 4 bits, which is included in the eleventh transfer data TD11 loaded onto the data input and output line GIO, and data inversion information of 12 bits, which is included in the twelfth transfer data TD12 loaded onto the data input and output line GIO. The data control circuit 240 generates the error correction signal EC based on error information of 4 bits, which is included in the eleventh transfer data TD11 loaded onto the data input and output line GIO, and error information of 12 bits, which is included in the twelfth transfer data TD12 loaded onto the data input and output line GIO.

After the start of the write operation of the normal operation, the repeater 250 generates the internal data ID of 256 bits based on the first to eleventh transfer data TD1 to TD11 of 256 bits, which are loaded onto the data input and output line GIO, and outputs the internal data ID to the internal input and output line INIO. In this case, the repeater 250 generates the internal data ID by inverting or non-inverting the first to eleventh transfer data TD1 to TD11 of 256 bits based on the data inversion signal DBI, and outputs the internal data ID to the internal input and output line INIO. The repeater 250 generates the internal data ID by correcting a bit including an error, among the first to eleventh transfer data TD1 to TD11 of 256 bits, based on the error correction signal EC, and outputs the internal data ID to the internal input and output line INIO.

When the write signal WT is generated, the data storage circuit 260 stores the internal data ID of 256 bits, which are loaded onto the internal input and output line INIO, in the memory cell region (MC in FIG. 7) of a bank selected from among the first to sixteenth banks (261-1 to 261-16 in FIG. 7) based on the first to sixteenth bits BAD<1:16> of the bank address and the first to sixty-fourth bits CAD<1:64> of the column address.

When the write signal WT is generated, the meta storage circuit 270 selects any one of the first to sixteenth register circuits (273-1 to 273-16 in FIG. 10) based on the first to fourth bits ADD<1:4> of the address and the fifth to eighth bits ADD<5:8> of the address, selects a plurality of registers included in the selected register circuit, and stores the twelfth transfer data TD12 of 24 bits, which are loaded onto the meta input and output line MIO.

The normal operation according to an embodiment of the present disclosure is described with reference to FIG. 14. In this case, a read operation through the data input and output circuit 230, the data storage circuit 260, and the meta storage circuit 270, is described as follows.

The command decoding circuit 210 generates the read signal RD by decoding the first to L-th bits CMD<1:L> of the command.

The address decoding circuit 220 generates the first to sixteenth bits BAD<1:16> of the bank address and the first to sixty-fourth bits CAD<1:64> of the column address by decoding the first to tenth bits ADD<1:10> of the address.

When the read signal RD is generated, the data storage circuit 260 outputs the internal data ID of 256 bits, which are stored in the memory cell region (MC in FIG. 7) of a bank selected from among the first to sixteenth banks (261-1 to 261-16 in FIG. 7), to the internal input and output line INIO based on the first to sixteenth bits BAD<1:16> of the bank address and the first to sixty-fourth bits CAD<1:64> of the column address.

When the read signal RD is generated, the meta storage circuit 270 selects any one of the first to sixteenth register circuits (273-1 to 273-16 in FIG. 10) based on the first to fourth bits ADD<1:4> of the address and the fifth to eighth bits ADD<5:8> of the address, selects a plurality of registers included in the selected register circuit, and outputs the twelfth transfer data TD12 of 24 bits, which are stored in the plurality of registers, to the meta input and output line MIO.

After the start of the read operation of the normal operation, the repeater 250 generates the first to tenth transfer data TD1 to TD10 each including 24 bits and the eleventh transfer data TD11 of 16 bits based on the internal data ID of 256 bits, which are loaded onto the internal input and output line INIO. The repeater 250 outputs the first to eleventh transfer data TD1 to TD11 of 256 bits to the data input and output line GIO.

After the start of the read operation of the normal operation, the first data transfer circuit 231-1 generates the first data DATA1 of 24 bits by receiving the first transfer data TD1 of 24 bits, which are loaded onto the data input and output line GIO, in synchronization with the data clock WCK, and outputs the first data DATA1 to the controller 10.

After the start of the read operation of the normal operation, the second to tenth data transfer circuits 231-2 to 231-10 generate the second to tenth data DATA2 to DATA10 each including 24 bits, respectively, by receiving the second to tenth transfer data TD2 to TD10 each including 24 bits, which are loaded onto the data input and output line GIO, respectively, in synchronization with the data clock WCK, and output the second to tenth data DATA2 to DATA10 to the controller 10.

After the start of the read operation of the normal operation, the eleventh data transfer circuit 231-11 generates the eleventh data DATA11 of 16 bits by receiving the eleventh transfer data TD11 of 16 bits, which are loaded onto the data input and output line GIO, in synchronization with the data clock WCK, and outputs the eleventh data DATA11 to the controller 10.

After the start of the read operation of the normal operation, the twelfth data transfer circuit 231-12 generates the twelfth data DATA12 of 24 bits by receiving the twelfth transfer data TD12 of 24 bits, which are loaded onto the meta input and output line MIO, in synchronization with the data clock WCK, and outputs the twelfth data DATA12 to the controller 10.

As described above, after the start of the normal operation, the semiconductor system 1 according to an embodiment of the present disclosure may input and output data and error information by using a plurality of memory cells and a plurality of registers.

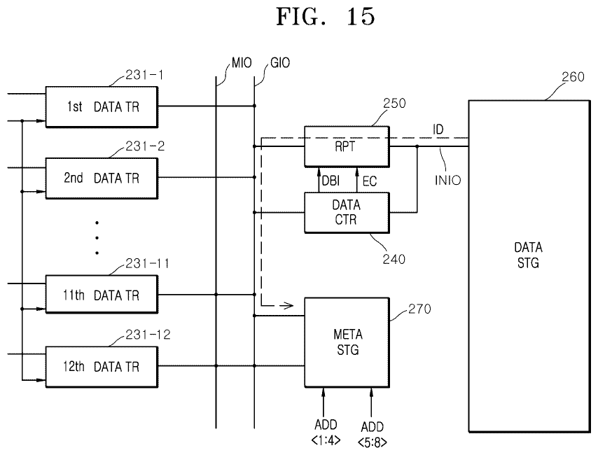

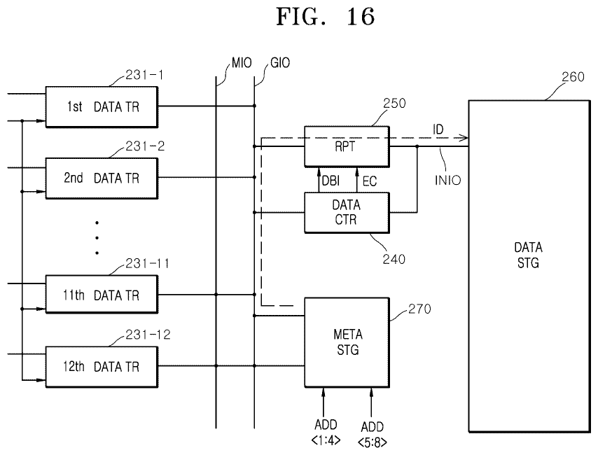

FIGS. 15 and 16 are diagrams for describing a meta write operation and meta read operation of the normal operation according to an embodiment of the present disclosure.

The meta write operation of the normal operation according to an embodiment of the present disclosure is described with reference to FIG. 15. In this case, the meta write operation through the data storage circuit 260 and the meta storage circuit 270 is described as follows.

The command decoding circuit 210 generates the meta write signal MWT by decoding the first to L-th bits CMD<1:L> of the command.

The address decoding circuit 220 generates the first to sixteenth bits BAD<1:16> of the bank address and the first to sixty-fourth bits CAD<1:64> of the column address by decoding the first to tenth bits ADD<1:10> of the address.

When the meta write signal MWT is generated, the data storage circuit 260 outputs the internal data ID stored in the memory cell region (MC in FIG. 7) of a bank selected from among the first to sixteenth banks (261-1 to 261-16 in FIG. 7) to the internal input and output line INIO based on the first to sixteenth bits BAD<1:16> of the bank address and the first to sixty-fourth bits CAD<1:64> of the column address.

After the start of the meta write operation of the normal operation, the repeater 250 generates the eleventh and twelfth transfer data TD11 and TD12 from the internal data ID loaded onto the internal input and output line INIO, and outputs the eleventh and twelfth transfer data TD11 and TD12 to the data input and output line GIO.

When the meta write signal MWT is generated, the meta storage circuit 270 selects any one of the first to sixteenth register circuits (273-1 to 273-16 in FIG. 10) based on the first to fourth bits ADD<1:4> of the address and the fifth to eighth bits ADD<5:8> of the address, selects a plurality of registers included in the selected register circuit, and stores the eleventh and twelfth transfer data TD11 and TD12 loaded onto the data input and output line GIO.

The meta read operation of the normal operation according to an embodiment of the present disclosure is described with reference to FIG. 16. In this case, the meta read operation through the data storage circuit 260 and the meta storage circuit 270 is described as follows.

The command decoding circuit 210 generates the meta read signal MRD by decoding the first to L-th bits CMD<1:L> of the command.

The address decoding circuit 220 generates the first to sixteenth bits BAD<1:16> of the bank address and the first to sixty-fourth bits CAD<1:64> of the column address by decoding the first to tenth bits ADD<1:10> of the address.

When the meta read signal MRD is generated, the meta storage circuit 270 selects any one of the first to sixteenth register circuits (273-1 to 273-16 in FIG. 10) based on the first to fourth bits ADD<1:4> of the address and the fifth to eighth bits ADD<5:8> of the address, selects a plurality of registers included in the selected register circuit, and outputs the eleventh and the second transfer data TD11 and TD12 stored in the plurality of registers to the data input and output line GIO.

After the start of the meta read operation of the normal operation, the repeater 250 generates the internal data ID from the eleventh and twelfth transfer data TD11 and TD12 loaded onto the data input and output line GIO, and outputs the internal data ID to the internal input and output line INIO.

When the meta read signal MRD is generated, the data storage circuit 260 stores the internal data ID in the memory cell region (MC in FIG. 7) of a bank selected from among the first to sixteenth banks (261-1 to 261-16 in FIG. 7) based on the first to sixteenth bits BAD<1:16> of the bank address and the first to sixty-fourth bits CAD<1:64> of the column address.

As described above, after the start of the meta write operation and meta read operation of the normal operation, the semiconductor system 1 according to an embodiment of the present disclosure may input and output error information of data by using a plurality of memory cells and a plurality of registers connected to the data input and output line GIO that is included in the semiconductor system 1.

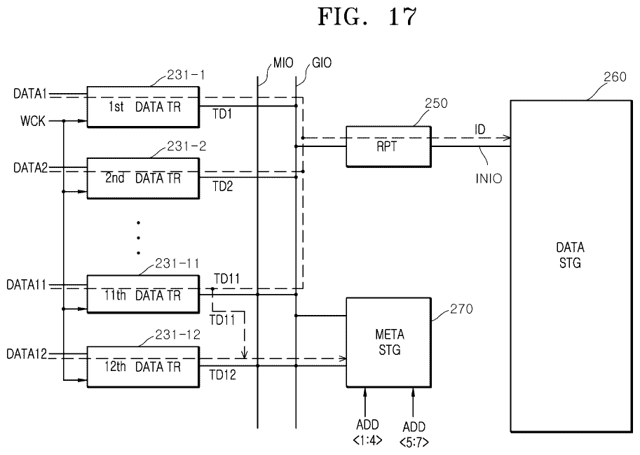

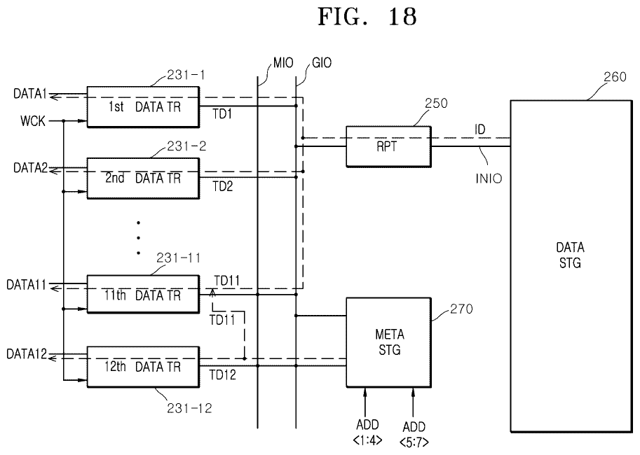

FIGS. 17 and 18 are diagrams for describing the first mode of the training operation according to an embodiment of the present disclosure.

The first mode of the training operation according to an embodiment of the present disclosure is described with reference to FIG. 17. In this case, a write operation through the data input and output circuit 230, the data storage circuit 260, and the meta storage circuit 270 is described as follows.

The command decoding circuit 210 generates the write signal WT by decoding the first to L-th bits CMD<1:L> of the command.

The address decoding circuit 220 generates the first to sixteenth bits BAD<1:16> of the bank address and the first to sixty-fourth bits CAD<1:64> of the column address by decoding the first to tenth bits ADD<1:10> of the address.

In the first mode of the training operation, after the start of the write operation, the first data transfer circuit 231-1 generates the first transfer data TD1 of 24 bits by receiving the first data DATA1 of 24 bits in synchronization with the data clock WCK, and outputs the first transfer data TD1 to the data input and output line GIO.

In the first mode of the training operation, after the start of the write operation, the second to tenth data transfer circuits 231-2 to 231-10 generate the second to tenth transfer data TD2 to TD10 each including 24 bits, respectively, by receiving the second to tenth data DATA2 to DATA10 each including 24 bits, respectively, in synchronization with the data clock WCK, and outputs the second to tenth transfer data TD2 to TD10 to the data input and output line GIO.

In the first mode of the training operation, after the start of the write operation, the eleventh data transfer circuit 231-11 generates the eleventh transfer data TD11 of 24 bits by receiving the eleventh data DATA11 of 24 bits in synchronization with the data clock WCK, and outputs the eleventh transfer data TD11 to the data input and output line GIO and the meta input and output line MIO. In this case, 16 bits to be stored in the data storage circuit 260, among the eleventh transfer data TD11 of 24 bits, are output to the data input and output line GIO. 8 bits to be stored in the meta storage circuit 270, among the eleventh transfer data TD11 of 24 bits, are output to the meta input and output line MIO.

In the first mode of the training operation, after the start of the write operation, the twelfth data transfer circuit 231-12 generates the twelfth transfer data TD12 of 24 bits by receiving the twelfth data DATA12 of 24 bits in synchronization with the data clock WCK, and outputs the twelfth transfer data TD12 to the meta input and output line MIO.

In the first mode of the training operation, after the start of the write operation, the repeater 250 generates the internal data ID of 256 bits based on the first to eleventh transfer data TD1 to TD11 of 256 bits, which are loaded onto the data input and output line GIO, and outputs the internal data ID to the internal input and output line INIO.

When the write signal WT is generated, the data storage circuit 260 stores the internal data ID of 256 bits, which are loaded onto the internal input and output line INIO, in the memory cell region (MC in FIG. 7) of a bank selected from among the first to sixteenth banks (261-1 to 261-16 in FIG. 7) based on the first to sixteenth bits BAD<1:16> of the bank address and the first to sixty-fourth bits CAD<1:64> of the column address.

When the write signal WT is generated, the meta storage circuit 270 selects any one of the first to sixteenth register circuits (273-1 to 273-16 in FIG. 10) based on the first to fourth bits ADD<1:4> of the address and the fifth to seventh bits ADD<5:7> of the address, selects a plurality of registers included in the selected register circuit, and stores the eleventh transfer data TD11 and the twelfth transfer data TD12 of 32 bits, which are loaded onto the meta input and output line MIO.

The first mode of the training operation according to an embodiment of the present disclosure is described with reference to FIG. 18. In this case, a read operation through the data input and output circuit 230, the data storage circuit 260, and the meta storage circuit 270 is described as follows.

The command decoding circuit 210 generates the read signal RD by decoding the first to L-th bits CMD<1:L> of the command.

The address decoding circuit 220 generates the first to sixteenth bits BAD<1:16> of the bank address and the first to sixty-fourth bits CAD<1:64> of the column address by decoding the first to tenth bits ADD<1:10> of the address.

When the read signal RD is generated, the data storage circuit 260 outputs the internal data ID of 256 bits, which are stored in the memory cell region (MC in FIG. 7) of a bank selected from among the first to sixteenth banks (261-1 to 261-16 in FIG. 7), to the internal input and output line INIO based on the first to sixteenth bits BAD<1:16> of the bank address and the first to sixty-fourth bits CAD<1:64> of the column address.

When the read signal RD is generated, the meta storage circuit 270 selects any one of the first to sixteenth register circuits (273-1 to 273-16 in FIG. 10) based on the first to fourth bits ADD<1:4> of the address and the fifth to seventh bits ADD<5:7> of the address, selects a plurality of registers included in the selected register circuit, and outputs the eleventh transfer data TD11 and the twelfth transfer data TD12 of 32 bits, which are stored in the plurality of registers, to the meta input and output line MIO.

In the first mode of the training operation, after the start of the read operation, the repeater 250 generates the first to tenth transfer data TD1 to TD10 each including 24 bits and the eleventh transfer data TD11 of 16 bits based on the internal data ID of 256 bits, which are loaded onto the internal input and output line INIO. The repeater 250 outputs the first to eleventh transfer data TD1 to TD11 of 256 bits to the data input and output line GIO.

In the first mode of the training operation, after the start of the read operation, the first data transfer circuit 231-1 generates the first data DATA1 of 24 bits by receiving the first transfer data TD1 of 24 bits, which are loaded onto the data input and output line GIO, in synchronization with the data clock WCK, and outputs the first data DATA1 to the controller 10.

In the first mode of the training operation, after the start of the read operation, the second to tenth data transfer circuits 231-2 to 231-10 generate the second to tenth data DATA2 to DATA10 each including 24 bits, respectively, by receiving the second to tenth transfer data TD2 to TD10 each including 24 bits, which are loaded onto the data input and output line GIO, in synchronization with the data clock WCK, and output the second to tenth data DATA2 to DATA10 to the controller 10.

In the first mode of the training operation, after the start of the read operation, the eleventh data transfer circuit 231-11 generates the eleventh data DATA11 of 24 bits by receiving the eleventh transfer data TD11 of 16 bits, which are loaded onto the data input and output line GIO, and the eleventh transfer data TD11 of 8 bits, which are loaded onto the meta input and output line MIO, in synchronization with the data clock WCK, and outputs the eleventh data DATA11 to the controller 10.

In the first mode of the training operation, after the start of the read operation, the twelfth data transfer circuit 231-12 generates the twelfth data DATA12 of 24 bits by receiving the twelfth transfer data TD12 of 24 bits, which are loaded onto the meta input and output line MIO, in synchronization with the data clock WCK, and outputs the twelfth data DATA12 to the controller 10.

As described above, the semiconductor system 1 according to an embodiment of the present disclosure may learn data and the data clock with data having a long pattern by using a plurality of memory cells and a plurality of registers after the start of the training operation. After the start of the training operation, the semiconductor system 1 may learn data and the data clock that input and output error information with data having a long pattern through the meta storage circuit that inputs and outputs error information.

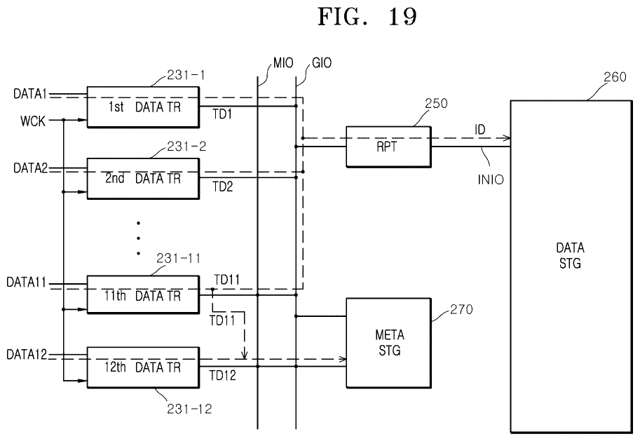

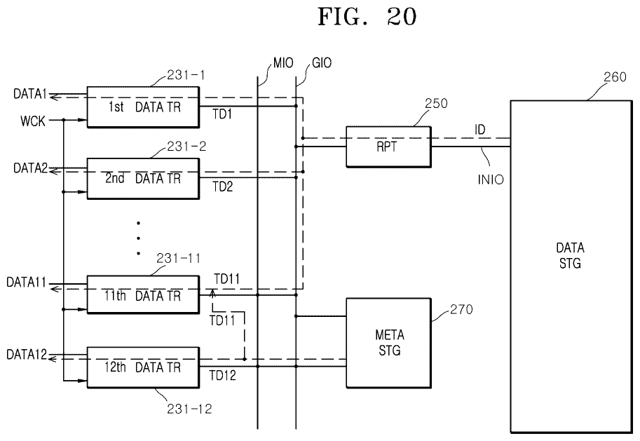

FIGS. 19 and 20 are diagrams for describing the second mode of the training operation according to an embodiment of the present disclosure.

The second mode of the training operation according to an embodiment of the present disclosure is described with reference to FIG. 19. In this case, a write operation through the data input and output circuit 230, the data storage circuit 260, and the meta storage circuit 270 is described as follows.

The command decoding circuit 210 generates the write signal WT by decoding the first to L-th bits CMD<1:L> of the command.

The address decoding circuit 220 generates the first to sixteenth bits BAD<1:16> of the bank address and the first to sixty-fourth bits CAD<1:64> of the column address by decoding the first to tenth bits ADD<1:10> of the address.

In the second mode of the training operation, after the start of the write operation, the first data transfer circuit 231-1 generates the first transfer data TD1 of 24 bits by receiving the first data DATA1 of 24 bits in synchronization with the data clock WCK, and outputs the first transfer data TD1 to the data input and output line GIO.

In the second mode of the training operation, after the start of the write operation, the second to tenth data transfer circuits 231-2 to 231-10 generate the second to tenth transfer data TD2 to TD10 each including 24 bits, respectively, by receiving the second to tenth data DATA2 to DATA10 each including 24 bits, respectively, in synchronization with the data clock WCK, and output the second to tenth transfer data TD2 to TD10 to the data input and output line GIO.

In the second mode of the training operation, after the start of a write operation, the eleventh data transfer circuit 231-11 generates the eleventh transfer data TD11 of 24 bits by receiving the eleventh data DATA11 of 24 bits in synchronization with the data clock WCK, and outputs the eleventh transfer data TD11 to the data input and output line GIO and the meta input and output line MIO. In this case, 16 bits to be stored in the data storage circuit 260, among the eleventh transfer data TD11 of 24 bits, are output to the data input and output line GIO. 8 bits to be stored in the meta storage circuit 270, among the eleventh transfer data TD11 of 24 bits, are output to the meta input and output line MIO.

In the first mode of the training operation, after the start of the write operation, the twelfth data transfer circuit 231-12 generates the twelfth transfer data TD12 of 24 bits by receiving the twelfth data DATA12 of 24 bits in synchronization with the data clock WCK, and outputs the twelfth transfer data TD12 to the meta input and output line MIO.

In the second mode of the training operation, after the start of the write operation, the repeater 250 generates the internal data ID of 256 bits based on the first to eleventh transfer data TD1 to TD11 of 256 bits, which are loaded onto the data input and output line GIO, and outputs the internal data ID to the internal input and output line INIO.

When the write signal WT is generated, the data storage circuit 260 stores the internal data ID of 256 bits, which are loaded onto the internal input and output line INIO, in the memory cell region (MC in FIG. 7) of a bank selected from among the first to sixteenth banks (261-1 to 261-16 in FIG. 7) based on the first to sixteenth bits BAD<1:16> of the bank address and the first to sixty-fourth bits CAD<1:64> of the column address.

In the second mode of the training operation, when the write signal WT is generated, the meta storage circuit 270 stores the eleventh transfer data TD11 and the twelfth transfer data TD12 of 32 bits, which are loaded onto the meta input and output line MIO, in a plurality of registers that are included in the register circuit and are sequentially selected regardless of the address ADD<1:8>.

The second mode of the training operation according to an embodiment of the present disclosure is described with reference to FIG. 20. In this case, a read operation through the data input and output circuit 230, the data storage circuit 260, and the meta storage circuit 270 is described as follows.

The command decoding circuit 210 generates the read signal RD by decoding the first to L-th bits CMD<1:L> of the command.

The address decoding circuit 220 generates the first to sixteenth bits BAD<1:16> of the bank address and the first to sixty-fourth bits CAD<1:64> of the column address by decoding the first to tenth bits ADD<1:10> of the address.

When the read signal RD is generated, the data storage circuit 260 outputs the internal data ID of 256 bits, which are stored in the memory cell region (MC in FIG. 7) of a bank selected from among the first to sixteenth banks (261-1 to 261-16 in FIG. 7) to the internal input and output line INIO based on the first to sixteenth bits BAD<1:16> of the bank address and the first to sixty-fourth bits CAD<1:64> of the column address.

In the second mode of the training operation, when the read signal RD is generated, the meta storage circuit 270 outputs, to the meta input and output line MIO, the eleventh transfer data TD11 and the twelfth transfer data TD12 of 32 bits, which are stored in a plurality of registers that are included in the register circuit and are sequentially selected regardless of the address ADD<1:8>. In the second mode of the training operation, after the start of the read operation, an operation of sequentially outputting the eleventh transfer data TD11 and the twelfth transfer data TD12 that are internally stored from a register that is first selected in a write operation means a first in first out (FIFO) operation.

In the second mode of the training operation, after the start of the read operation, the repeater 250 generates the first to tenth transfer data TD1 to TD10 each including 24 bits and the eleventh transfer data TD11 of 16 bits based on the internal data ID of 256 bits, which are loaded onto the internal input and output line INIO. The repeater 250 outputs the first to eleventh transfer data TD1 to TD11 of 256 bits to the data input and output line GIO.

In the second mode of the training operation, after the start of the read operation, the first data transfer circuit 231-1 generates the first data DATA1 of 24 bits by receiving the first transfer data TD1 of 24 bits, which are loaded onto the data input and output line GIO, in synchronization with the data clock WCK, and outputs the first data DATA1 to the controller 10.

In the second mode of the training operation, after the start of the read operation, the second to tenth data transfer circuits 231-2 to 231-10 generate the second to tenth data DATA2 to DATA10 each including 24 bits, respectively, by receiving the second to tenth transfer data TD2 to TD10 each including 24 bits, respectively, which are loaded onto the data input and output line GIO, in synchronization with the data clock WCK, and output the second to tenth data DATA2 to DATA10 to the controller 10.

In the second mode of the training operation, after the start of the read operation, the eleventh data transfer circuit 231-11 generates the eleventh data DATA11 of 24 bits by receiving the eleventh transfer data TD11 of 16 bits, which are loaded onto the data input and output line GIO, and the eleventh transfer data TD11 of 8 bits, which are loaded onto the meta input and output line MIO, in synchronization with the data clock WCK, and outputs the eleventh data DATA11 to the controller 10.

In the second mode of the training operation, after the start of the read operation, the twelfth data transfer circuit 231-12 generates the twelfth data DATA12 of 24 bits by receiving the twelfth transfer data TD12 of 24 bits, which are loaded onto the meta input and output line MIO, in synchronization with the data clock WCK, and outputs the twelfth data DATA12 to the controller 10.

As described above, the semiconductor system 1 according to an embodiment of the present disclosure may learn data and the data clock with data having a long pattern by using a plurality of memory cells and a plurality of registers after the start of the training operation. After the start of the training operation, the semiconductor system 1 may learn data and the data clock that inputs and outputs error information with data having a long pattern through the meta storage circuit that inputs and outputs error information.

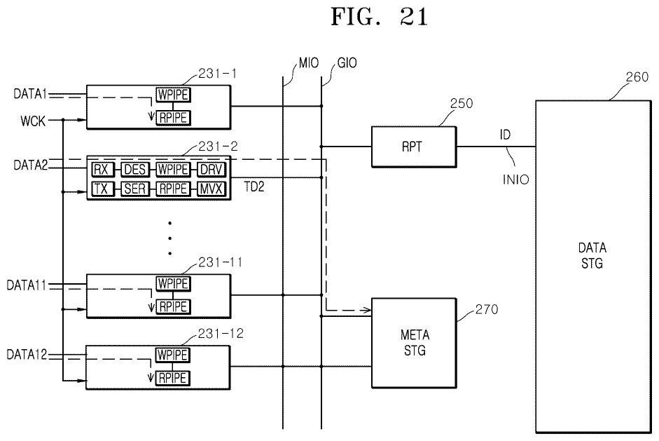

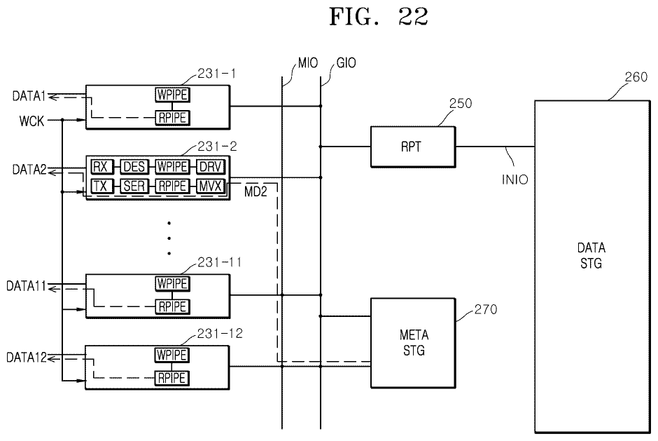

FIGS. 21 and 22 are diagrams for describing the third mode of the training operation according to an embodiment of the present disclosure.

A case in which a transmission characteristic in which the second data transfer circuit 231-2 transmits the second data DATA2 in the third mode of the training operation according to an embodiment of the present disclosure is low is described as an example with reference to FIG. 21. In this case, a write operation through the data input and output circuit 230, the data storage circuit 260, and the meta storage circuit 270 is described as follows.

The command decoding circuit 210 generates the write signal WT by decoding the first to L-th bits CMD<1:L> of the command.

The address decoding circuit 220 generates the first to sixteenth bits BAD<1:16> of the bank address and the first to sixty-fourth bits CAD<1:64> of the column address by decoding the first to tenth bits ADD<1:10> of the address.

In the third mode of the training operation, after the start of the write operation, the first data transfer circuit 231-1 receives the first data DATA1 of 24 bits in synchronization with the data clock WCK, and stores the first data DATA1 of 24 bits in the write pipe WPIPE and the read pipe RPIPE.

The receiver RX of the second data transfer circuit 231-2 receives the second data DATA2 of 24 bits through the pad 311 in synchronization with a rising edge and falling edge of the write clock WCK, and outputs, to the parallel conversion circuit DES, the second data DATA2 of 24 bits received in synchronization with the rising edge and falling edge of the write clock WCK.

The parallel conversion circuit DES of the second data transfer circuit 231-2 generates the write data WD by converting the second data DATA2 of 24 bits that are input in series through the receiver RX in parallel, and outputs the write data WD that have been converted in parallel to the write pipe circuit WPIPE.

The write pipe circuit WPIPE of the second data transfer circuit 231-2 latches the write data WD of 24 bits that have been converted in parallel, and outputs the latched write data WD to the driver DRV.

The driver DRV of the second data transfer circuit 231-2 generates the second transfer data TD2 of 24 bits based on the write data WD of 24 bits, and outputs the second transfer data TD2 of 24 bits to the plurality of data input and output lines GIO.

In the third mode of the training operation, after the start of the write operation, the third to twelfth data transfer circuits 231-3 to 231-12 receive the third to twelfth data DATA3 to DATA12 each including 24 bits, respectively, in synchronization with the data clock WCK, and store the third to twelfth data DATA3 to DATA12 each including 24 bits in the write pipe WPIPE and the read pipe RPIPE.

In the third mode of the training operation, when the write signal WT is generated, the meta storage circuit 270 stores the second transfer data TD2 of 24 bits, which are loaded onto the data input and output line GIO, in a plurality of registers that are included in the register circuit and are sequentially selected regardless of the address ADD<1:8>.

A case in which a transmission characteristic in which the second data transfer circuit 231-2 transmits the second data DATA2 in the third mode of a training operation according to an embodiment of the present disclosure is low is described as an example with reference to FIG. 22. In this case, a read operation through the data input and output circuit 230, the data storage circuit 260, and the meta storage circuit 270 is described as follows.

The command decoding circuit 210 generates the read signal RD by decoding the first to L-th bits CMD<1:L> of the command.

The address decoding circuit 220 generates the first to sixteenth bits BAD<1:16> of the bank address and the first to sixty-fourth bits CAD<1:64> of the column address by decoding the first to tenth bits ADD<1:10> of the address.

In the third mode of the training operation, when the read signal RD is generated, the meta storage circuit 270 outputs, to the meta input and output line MIO, the second test meta data MD2 generated from the second transfer data TD2 of 24 bits stored in a plurality of registers that are included in the register circuit and are sequentially selected regardless of the address ADD<1:8>. In the third mode of the training operation, after the start of the read operation, an operation of sequentially outputting the second test meta data MD2 generated from the second transfer data TD2 that are internally stored from a register that is first selected in a write operation means a first in first out (FIFO) operation.

In the third mode of the training operation, after the start of the read operation, the first data transfer circuit 231-1 outputs the first transfer data TD1 of 24 bits that are stored in the read pipe RPIPE to the controller 10 in synchronization with the data clock WCK.

The multiplexer MUX of the second data transfer circuit 231-2 receives the second test meta data MD2 of 24 bits, which are loaded onto the meta input and output line MIO, from the meta storage circuit 270, and outputs the second test meta data MD2 of 24 bits to the read pipe circuit RPIPE.

The read pipe circuit RPIPE of the second data transfer circuit 231-2 generates the second latch data LD2 by receiving the second test meta data MD2 of 24 bits from the multiplexer MUX, and outputs the second latch data LD2 of 24 bits to the serial conversion circuit 313-3.

The serial conversion circuit SER of the second data transfer circuit 231-2 generates the second read data RD2 by converting the second latch data LD2 of 24 bits that are input in parallel through the read pipe circuit 313-2 in series, and outputs the second read data RD2 of 24 bits that have been converted in series to the transmitter TX.

The transmitter TX of the second data transfer circuit 231-2 receives the second read data RD2 of 24 bits through the serial conversion circuit SER in synchronization with a rising edge and falling edge of the write clock WCK, generates the second data DATA2 from the received second read data RD2 of 24 bits, and outputs the second data DATA2 to the controller 10 through the pad DQ.

In the third mode of the training operation, after the start of the read operation, the third to twelfth data transfer circuits 231-3 to 231-12 outputs the third to twelfth transfer data TD3 to TD12 each including 24 bits, which are stored in the read pipe RPIPE, to the controller 10 in synchronization with the data clock WCK.

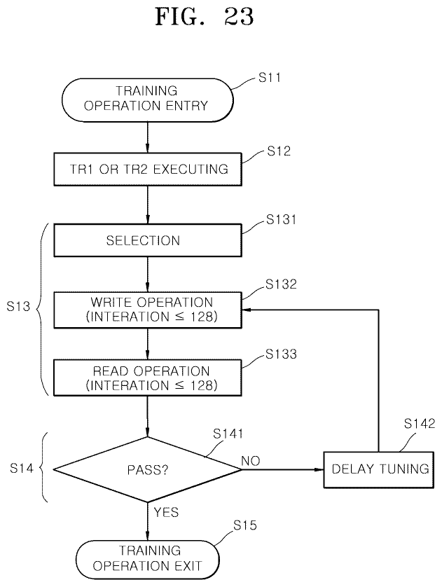

FIG. 23 is a flowchart for describing the first mode and second mode of the training operation according to an embodiment of the present disclosure.

The first mode of the training operation according to an embodiment of the present disclosure is described as follows with reference to FIG. 23.

The training operation may include a training operation entry process S11, a mode setting process S12, a write operation and read operation process S13, a training operation execution process S14, and a training operation exit process S15.

The training operation entry process S11 may be set as a process of entering the training operation based on the command CMD and the address ADD.

In the training operation entry process S11, the controller 10 may transmit the command CMD and the address ADD that perform the first mode of the training operation to the memory device 20.

The mode setting process S12 may be set as a process of generating the write signal WT, the read signal RD, and the first bit TR<1> of the training signal by decoding the command CMD and the address ADD to perform the first mode of the training operation.

In the mode setting process S12, the command decoding circuit 210 may generate the write signal WT, the read signal RD, and the first bit TR<1> of the training signal by decoding the first to L-th bits CMD<1:L> of the command. In the mode setting process S12, the address decoding circuit 220 may generate the first to sixteenth bits BAD<1:16> of the bank address and the first to sixty-fourth bits CAD<1:64> of the column address by decoding the first to tenth bits ADD<1:10> of the address.

The write operation and read operation process S13 may be set as an operation of inputting and outputting the first to twelfth data DATA1 to DATA12 by performing a write operation and read operation of the training operation.

The write operation and read operation process S13 may include a selection process S131, a write operation process S132, and a read operation process S133.

The selection process S131 may be set as an operation of selecting the first to sixteenth banks (261-1 to 261-16 in FIG. 7) of the data storage circuit 260 and the first to sixteenth register circuits (273-1 to 273-16 in FIG. 10) of the meta storage circuit 270 based on the first to sixteenth bits BAD<1:16> of the bank address and the first to sixty-fourth bits CAD<1:64> of the column address.

In the selection process S131, any one of the first to sixteenth banks (261-1 to 261-16 in FIG. 7) may be selected based on the first to sixteenth bits BAD<1:16> of the bank address and the first to sixty-fourth bits CAD<1:64> of the column address. In the selection process S131, any one of the first to sixteenth register circuits (273-1 to 273-16 in FIG. 10) may be selected based on the first to fourth bits ADD<1:4> of the address and the fifth to seventh bits ADD<5:7> of the address.

The write operation process S132 may be set as a process of performing a write operation.

In the write operation process S132, in the first mode of the training operation, after the start of a write operation, the first data transfer circuit 231-1 may generate the first transfer data TD1 of 24 bits by receiving the first data DATA1 of 24 bits in synchronization with the data clock WCK, and may output the first transfer data TD1 to the data input and output line GIO. In the write operation process S132, in the first mode of the training operation, after the start of the write operation, the second to tenth data transfer circuits 231-2 to 231-10 may generate the second to tenth transfer data TD2 to TD10 each including 24 bits by receiving the second to tenth data DATA2 to DATA10 each including 24 bits in synchronization with the data clock WCK, and may output the second to tenth transfer data TD2 to TD10 to the data input and output line GIO. In the write operation process S132, in the first mode of the training operation, after the start of the write operation, the eleventh data transfer circuit 231-11 may generate the eleventh transfer data TD11 of 24 bits by receiving the eleventh data DATA11 of 24 bits in synchronization with the data clock WCK, and may output the eleventh transfer data TD11 to the data input and output line GIO and the meta input and output line MIO. In this case, 16 bits to be stored in the data storage circuit 260, among the eleventh transfer data TD11 of 24 bits, may be output to the data input and output line GIO. 8 bits to be stored in the meta storage circuit 270, among the eleventh transfer data TD11 of 24 bits, may be output to the meta input and output line MIO. In the write operation process S132, in the first mode of the training operation, after the start of the write operation, the twelfth data transfer circuit 231-12 may generate the twelfth transfer data TD12 of 24 bits by receiving the twelfth data DATA12 of 24 bits in synchronization with the data clock WCK, and may output the twelfth transfer data TD12 to the meta input and output line MIO.

In the write operation process S132, in the first mode of the training operation, after the start of the write operation, the repeater 250 may generate the internal data ID of 256 bits based on the first to eleventh transfer data TD1 to TD11 of 256 bits, which are loaded onto the data input and output line GIO, and may output the internal data ID to the internal input and output line INIO.

In the write operation process S132, when the write signal WT is generated, the data storage circuit 260 may store the internal data ID of 256 bits, which are loaded onto the internal input and output line INIO, in the memory cell region (MC in FIG. 7) of a bank selected from among the first to sixteenth banks (261-1 to 261-16 in FIG. 7) based on the first to sixteenth bits BAD<1:16> of the bank address and the first to sixty-fourth bits CAD<1:64> of the column address.

In the write operation process S132, when the write signal WT is generated, the meta storage circuit 270 may select any one of the first to sixteenth register circuits (273-1 to 273-16 in FIG. 10) based on the first to fourth bits ADD<1:4> of the address and the fifth to seventh bits ADD<5:7> of the address, may select a plurality of registers included in the selected register circuit, and may store the eleventh transfer data TD11 and the twelfth transfer data TD12 of 32 bits, which are loaded onto the meta input and output line MIO.

The write operation may be repeatedly performed 128 times. In the first mode of the training operation, the first to sixteenth register circuits (273-1 to 273-16 in FIG. 10) of the meta storage circuit 270 can store data of 4,096 bits (4 kilobits) by repeatedly storing data of 32 bits. Accordingly, the write operations can be repeatedly performed 128 times.

In the read operation process S133, when the read signal RD is generated, the data storage circuit 260 may output the internal data ID of 256 bits, which are stored in the memory cell region (MC in FIG. 7) of a bank selected from among the first to sixteenth banks (261-1 to 261-16 in FIG. 7) to the internal input and output line INIO based on the first to sixteenth bits BAD<1:16> of the bank address and the first to sixty-fourth bits CAD<1:64> of the column address.

In the read operation process S133, when the read signal RD is generated, the meta storage circuit 270 may select any one of the first to sixteenth register circuits (273-1 to 273-16 in FIG. 10) based on the first to fourth bits ADD<1:4> of the address and the fifth to eighth bits ADD<5:8> of the address, may select a plurality of registers included in the selected register circuit, and may output the stored twelfth transfer data TD12 of 24 bits to the meta input and output line MIO.

In the read operation process S133, after the start of a read operation of the normal operation, the repeater 250 may generate the first to tenth transfer data TD1 to TD10 each including 24 bits and the eleventh transfer data TD11 of 16 bits based on the internal data ID of 256 bits, which are loaded onto the internal input and output line INIO. The repeater 250 may output the first to eleventh transfer data TD1 to TD11 of 256 bits to the data input and output line GIO.

In the read operation process S133, after the start of the read operation of the normal operation, the first data transfer circuit 231-1 may generate the first data DATA1 of 24 bits by receiving the first transfer data TD1 of 24 bits, which are loaded onto the data input and output line GIO, in synchronization with the data clock WCK, and may output the first data DATA1 to the controller 10. In the read operation process S133, after the start of the read operation of the normal operation, the second to tenth data transfer circuits 231-2 to 231-10 may generate the second to tenth data DATA2 to DATA10 each including 24 bits, respectively, by receiving the second to tenth transfer data TD2 to TD10 each including 24 bits, which are loaded onto the data input and output line GIO, respectively, in synchronization with the data clock WCK, and may output the second to tenth data DATA2 to DATA10 to the controller 10. In the read operation process S133, after the start of the read operation of the normal operation, the eleventh data transfer circuit 231-11 may generate the eleventh data DATA11 of 16 bits by receiving the eleventh transfer data TD11 of 16 bits, which are loaded onto the data input and output line GIO, in synchronization with the data clock WCK, and may output the eleventh data DATA11 to the controller 10. In the read operation process S133, after the start of the read operation of the normal operation, the twelfth data transfer circuit 231-12 may generate the twelfth data DATA12 of 24 bits by receiving the twelfth transfer data TD12 of 24 bits, which are loaded onto the meta input and output line MIO, in synchronization with the data clock WCK, and may output the twelfth data DATA12 to the controller 10.

The read operation may be repeatedly performed 128 times. In the first mode of the training operation, the first to sixteenth register circuits (273-1 to 273-16 in FIG. 10) of the meta storage circuit 270 may output data of 4,096 bits (4 kilobits) by repeatedly outputting data of 32 bits. Accordingly, the read operation can be repeatedly performed 128 times.

The training operation execution process S14 may be set as a process of matching timing at which the first to twelfth data DATA1 to DATA12 are output and timing at which the data clock WCK is output.

The training operation execution process S14 may include a sensing process S141 and a delay tuning process S142.

The sensing process S141 may be set as a process of sensing whether to tune a delay quantity by which the first to twelfth data DATA1 to DATA12 are output.

In the sensing process S141, the controller 10 may enter the training operation exit process S15 when a logic level combination of the first to twelfth data DATA1 to DATA12 output in a write operation of the training operation and a logic level combination of the first to twelfth data DATA1 to DATA12 received in the read operation of the training operation are identical with each other. In the sensing process S141, the controller 10 may enter the delay tuning process S142 when a logic level combination of the first to twelfth data DATA1 to DATA12 output in the write operation of the training operation and a logic level combination of the first to twelfth data DATA1 to DATA12 received in the read operation of the training operation are different from each other.

The delay tuning process S142 may be set as a process of tuning a delay quantity by which the first to twelfth data DATA1 to DATA12 are output.

In the delay tuning process S142, the controller 10 may output the delay quantity by which the first to twelfth data DATA1 to DATA12 are output by decreasing or increasing the delay quantity when a logic level combination of the first to twelfth data DATA1 to DATA12 output at a rising edge of the data clock WCK in the write operation of the training operation and a logic level combination of the first to twelfth data DATA1 to DATA12 received in the read operation of the training operation are different from each other.

The training operation exit process S15 may be set as a process of exiting the training operation.

The second mode of the training operation in which the second bit TR<2> of the training signal is generated instead of the first bit TR<1> of the training signal, the first to sixteenth register circuits (273-1 to 273-16 in FIG. 10) are sequentially selected regardless of the address, and a write operation and a read operation are repeatedly performed may be performed identically with the first mode of the training operation.

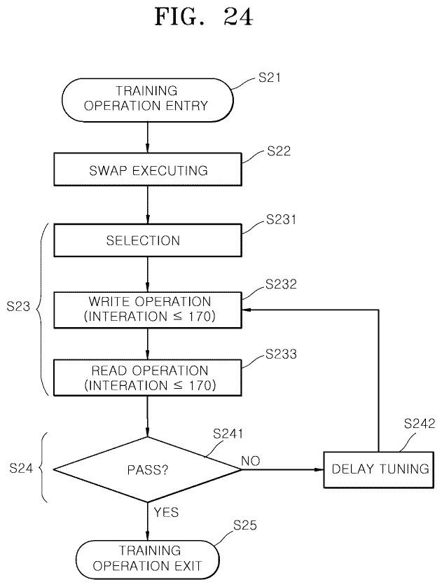

FIG. 24 is a flowchart for describing the third mode of the training operation according to an embodiment of the present disclosure.

The third mode of the training operation according to an embodiment of the present disclosure is described with reference to FIG. 24. In this case, an operation of performing the third mode of the training operation through the second data transfer circuit 231-2 is described as an example as follows.

The training operation may include a training operation entry process S21, a swap execution process S22, a write operation and read operation process S23, a training operation execution process S24, and a training operation exit process S25.

The training operation entry process S21 may be set as a process of entering the training operation based on the command CMD and the address ADD.

In the training operation entry process S21, the controller 10 may transmit the command CMD and the address ADD that perform the third mode of the training operation to the memory device 20.

The swap setting process S22 may be set as a process of generating the write signal WT, the read signal RD, and the third bit TR<3> of the training signal by decoding the command CMD and the address ADD to perform the third mode of the training operation.

In the swap setting process S22, the swap control circuit 12 may control the training operation for specific data, among the first to twelfth data DATA1 to DATA12. In the third mode of the training operation, the swap control circuit 12 may control the training operation to be performed on any one of the first to twelfth data DATA1 to DATA12 through the meta storage circuit 270.

In the swap setting process S22, the command decoding circuit 210 may generate the write signal WT, the read signal RD, and the third bit TR<3> of the training signal by decoding the first to L-th bits CMD<1:L> of the command. In the swap setting process S22, the address decoding circuit 220 may generate the first to sixteenth bits BAD<1:16> of the bank address and the first to sixty-fourth bits CAD<1:64> of the column address by decoding the first to tenth bits ADD<1:10> of the address.

The write operation and read operation process S23 may be set as an operation of inputting and outputting the first to twelfth data DATA1 to DATA12 by performing a write operation and read operation of the training operation.

The write operation and read operation process S23 may include a selection process S231, a write operation process S232, and a read operation process S233.

The selection process S231 may be set as an operation of sequentially selecting the first to sixteenth register circuits (273-1 to 273-16 in FIG. 10) of the meta storage circuit 270 regardless of the address.

In the selection process S231, the first to sixteenth register circuits (273-1 to 273-16 in FIG. 10) may be sequentially selected regardless of the address.

The write operation process S232 may be set as a process of performing a write operation.

In the write operation process S232, in the third mode of the training operation, after the start of the write operation, the first data transfer circuit 231-1 may receive the first data DATA1 of 24 bits in synchronization with the data clock WCK, and may store the first data DATA1 of 24 bits in the write pipe WPIPE and the read pipe RPIPE. In the write operation process S232, the receiver RX of the second data transfer circuit 231-2 may receive the second data DATA2 of 24 bits through the pad 311 in synchronization with a rising edge and falling edge of the write clock WCK, and may output the second data DATA2 of 24 bits, which are received in synchronization with the rising edge and falling edge of the write clock WCK, to the parallel conversion circuit DES. In the write operation process S232, the parallel conversion circuit DES of the second data transfer circuit 231-2 may generate the write data WD by converting the second data DATA2 of 24 bits that are input in series through the receiver RX in parallel, and may output the write data WD that have been converted in parallel to the write pipe circuit WPIPE. In the write operation process S232, the write pipe circuit WPIPE of the second data transfer circuit 231-2 may latch the write data WD of 24 bits that have been converted in parallel, and may output the latched write data WD to the driver DRV. In the write operation process S232, the driver DRV of the second data transfer circuit 231-2 may generate the second transfer data TD2 of 24 bits based on the write data WD of 24 bits, and may output the second transfer data TD2 of 24 bits to the plurality of data input and output lines GIO. In the write operation process S232, in the third mode of the training operation, after the start of the write operation, the third to twelfth data transfer circuits 231-3 to 231-12 may receive the third to twelfth data DATA3 to DATA12 each including 24 bits in synchronization with the data clock WCK, and may store the third to twelfth data DATA3 to DATA12 each including 24 bits in the write pipe WPIPE and the read pipe RPIPE.

In the write operation process S232, in the third mode of the training operation, when the write signal WT is generated, the meta storage circuit 270 may store the second transfer data TD2 of 24 bits, which are loaded onto the data input and output line GIO, in a plurality of registers that are included in the register circuit and are sequentially selected regardless of the address ADD<1:8>.

The write operation may be repeatedly performed 171 times. In the third mode of the training operation, the first to sixteenth register circuits (273-1 to 273-16 in FIG. 10) of the meta storage circuit 270 may store data of 4,096 bits (4 kilobits) by repeatedly storing data of 24 bits. Accordingly, the write operation may be repeatedly performed 170 times.

In the read operation process S23, in the third mode of the training operation, when the read signal RD is generated, the meta storage circuit 270 may generate the second test meta data MD2 from the second transfer data TD2 of 24 bits stored in a plurality of registers that are included in the register circuit and are sequentially selected regardless of the address ADD<1:8>, and may output the second test meta data MD2 to the meta input and output line MIO.

In the read operation process S23, in the third mode of the training operation, after the start of a read operation, the first data transfer circuit 231-1 may output the first transfer data TD1 of 24 bits stored in the read pipe RPIPE to the controller 10 in synchronization with the data clock WCK. In the read operation process S23, the multiplexer MUX of the second data transfer circuit 231-2 may receive the second test meta data MD2 of 24 bits, which are loaded onto the meta input and output line MIO, from the meta storage circuit 270, and may output the second test meta data MD2 of 24 bits to the read pipe circuit RPIPE. In the read operation process S23, the read pipe circuit RPIPE of the second data transfer circuit 231-2 may generate the latch data LD by receiving the second test meta data MD2 of 24 bits from the multiplexer MUX, and may output the latch data LD of 24 bits to the serial conversion circuit 313-3. In the read operation process S23, the serial conversion circuit SER of the second data transfer circuit 231-2 may generate the read data RD by converting the latch data LD of 24 bits that are input in parallel through the read pipe circuit 313-2 in series, and may output the read data RD of 24 bits that have been converted in series to the transmitter TX. In the read operation process S23, the transmitter TX of the second data transfer circuit 231-2 may receive the read data RD of 24 bits through the serial conversion circuit SER in synchronization with a rising edge and falling edge of the write clock WCK, may generate the first data DATA1 from the received read data RD of 24 bits, and may output the first data DATA1 to the controller 10 through the second pad DQ.

In the read operation process S23, in the third mode of the training operation, after the start of the read operation, the third to twelfth data transfer circuits 231-3 to 231-12 may output the third to twelfth transfer data TD3 to TD12 each including 24 bits, which are stored in the read pipe RPIPE, to the controller 10 in synchronization with the data clock WCK.

The read operation may be repeatedly performed 171 times. In the third mode of the training operation, the first to sixteenth register circuits (273-1 to 273-16 in FIG. 10) of the meta storage circuit 270 may store data of 4,096 bits (4 kilobits) by repeatedly outputting data of 24 bits. Accordingly, the read operation may be repeatedly performed 170 times.

The training operation execution process S24 may be set as a process of matching timing at which the first to twelfth data DATA1 to DATA12 are output and timing at which the data clock WCK is output.

The training operation execution process S24 may include a sensing process S241 and a delay tuning process S242.

The sensing process S241 may be set as a process of sensing whether to tune a delay quantity by which the first to twelfth data DATA1 to DATA12 are output.

In the sensing process S241, the controller 10 may enter the training operation exit process S25 when a logic level combination of the first to twelfth data DATA1 to DATA12 output in the write operation of the training operation and a logic level combination of the first to twelfth data DATA1 to DATA12 received in the read operation of the training operation are identical with each other. In the sensing process S241, the controller 10 may enter the delay tuning process S242 when a logic level combination of the first to twelfth data DATA1 to DATA12 output in the write operation of the training operation and a logic level combination of the first to twelfth data DATA1 to DATA12 received in the read operation of the training operation are different from each other.

The delay tuning process S242 may be set as a process of tuning a delay quantity by which the first to twelfth data DATA1 to DATA12 are output.

In the delay tuning process S242, the controller 10 may output the delay quantity by which the first to twelfth data DATA1 to DATA12 are output by decreasing or increasing the delay quantity when a logic level combination of the first to twelfth data DATA1 to DATA12 output in the write operation of the training operation and a logic level combination of the first to twelfth data DATA1 to DATA12 received in the read operation of the training operation are different from each other.

The training operation exit process S25 may be set as a process of exiting the training operation.

As described above, the training operation according to an embodiment of the present disclosure may be performed based on data and the data clock with data having a long pattern by using a plurality of memory cells and a plurality of registers. The training operation may be performed based on data and the data clock that input and output error information with data having a long pattern through the meta storage circuit that inputs and outputs error information.

Although embodiments of the present disclosure have been described for illustrative purposes, those skilled in the art will appreciate that various modifications, additions and substitutions are possible, without departing from the scope and spirit of the present disclosure. Therefore, the embodiments disclosed above and in the accompanying drawings should be considered in a descriptive sense only and not for limiting the technological scope. The technological scope of the present disclosure is not limited by the embodiments and the accompanying drawings. The spirit and scope of the present disclosure should be interpreted in connection with the appended claims and encompass all equivalents falling within the scope of the appended claims. Furthermore, the embodiments may be combined to form additional embodiments.

What is claimed is:

1. A semiconductor system comprising:
a controller configured to output first and second groups of data after a start of a write operation of a training operation, configured to receive the first and second groups of data after a start of a read operation of the training operation, and configured to tune a delay quantity by which the first and second groups of data are output; and
a memory device configured to receive the first group of data through a first group of data transfer circuits that input and output data, store the first group of data in a data storage circuit, receive the second group of data through a second group of data transfer circuits that input and output error information, and store the second group of data in a meta storage circuit after the start of the write operation of the training operation and further configured to output the first group of data stored in the data storage circuit to the controller and output the second group of data stored in the meta storage circuit to the controller after the start of the read operation of the training operation.

2. The semiconductor system of claim 1, wherein the controller tunes the delay quantity when a logic level combination of the first and second groups of data output in the write operation of the training operation and a logic level combination of the first and second groups of data received in the read operation of the training operation are different from each other.

3. The semiconductor system of claim 1, wherein the controller tunes the delay quantity by repeatedly outputting the first and second groups of data after the start of the write operation and repeatedly receiving the first and second groups of data after the start of the read operation.

4. The semiconductor system of claim 1, wherein the training operation is an operation of matching timing at which the first and second groups of data are output and timing at which a data clock is output, the data clock strobing the first and second groups of data.

5. The semiconductor system of claim 1, wherein:
the first group of data is a signal to be stored in the data storage circuit, and
the second group of data is a signal comprising the error information of the first group of data and data inversion information for inverting and transmitting the first group of data.

6. The semiconductor system of claim 1, wherein the memory device comprises:
a data input and output circuit configured to generate a first group of transfer data from the first group of data, output the first group of transfer data, generate a second group of transfer data from the second group of data, and output the second group of transfer data after the start of the write operation of the training operation, and further configured to generate the first group of data from the first group of transfer data, output the first group of data, generate the second group of data from the second group of transfer data, and output the second group of data after the start of the read operation of the training operation;
a repeater configured to generate internal data from the first group of transfer data loaded onto a data input and output line and output the internal data to the data storage circuit after the start of the write operation of the training operation, and further configured to generate the first group of transfer data from the internal data output by the data storage circuit and output the first group of transfer data to the data input and output line after the start of the read operation of the training operation; and
a meta storage circuit configured to store the second group of transfer data loaded onto a meta input and output line after the start of the write operation of the training operation and further configured to output the second group of transfer data stored to the meta input and output line after the start of the read operation of the training operation.

7. The semiconductor system of claim 6, wherein the data input and output circuit comprises:
the first group of data transfer circuits configured to generate the first group of transfer data from the first group of data and output the first group of transfer data to the data input and output line after the start of the write operation of the training operation and further configured to generate the first group of data from the first group of transfer data loaded onto the data input and output line and output the first group of data after the start of the read operation of the training operation; and
the second group of data transfer circuits configured to generate the second group of transfer data from the second group of data and output the second group of transfer data to the meta input and output line after the start of the write operation of the training operation and further configured to generate the second group of data from the second group of transfer data loaded onto the meta input and output line and output the second group of data after the start of the read operation of the training operation.

8. The semiconductor system of claim 1, wherein:
the data storage circuit comprises a plurality of banks, and
the data storage circuit is configured to store the first group of data in a bank, which is selected from among the plurality of banks based on an address, and output the stored first group of data.

9. The semiconductor system of claim 8, wherein:
the meta storage circuit comprises a plurality of registers, and
the meta storage circuit is configured to store the second group of data in a register, which is selected from among the plurality of registers based on the address, and output the stored second group of data.

10. The semiconductor system of claim 9, wherein a number of the plurality of registers included in the meta storage circuit is the same as a number of the plurality of banks included in the data storage circuit.

11. A memory device comprising:
a data input and output circuit configured to generate a first group of transfer data by receiving a first group of data, generate a second group of transfer data by receiving a second group of data after a start of a write operation of a training operation, and further configured to generate the first group of data by receiving the first group of transfer data generated from internal data and generate the second group of data by receiving the second group of transfer data, after the start of a read operation of the training operation;
a data storage circuit comprising a plurality of banks configured to store the internal data generated from the first group of transfer data in a bank, which is selected from among the plurality of banks based on an address after the start of the write operation of the training operation and further configured to output the internal data stored in the selected bank after the start of the read operation of the training operation; and
a meta storage circuit comprising a plurality of registers, configured to store the second group of data in a register, which is selected from among the plurality of registers based on the address after the start of the write operation of the training operation and further configured to output the second group of data stored in the selected register after the start of the read operation of the training operation.

12. The memory device of claim 11, wherein the data input and output circuit comprises:
a first group of data transfer circuits configured to input and output the first group of data to be stored in the data storage circuit; and
a second group of data transfer circuits configured to input and output the second group of data including error information of the first group of data.

13. The memory device of claim 11, wherein the data input and output circuit configured to input and output the first and second groups of data in units of first bit numbers in first and second modes of the training operation and in units of second bit numbers in a third mode of training operation.

14. The memory device of claim 11, wherein the training operation is an operation of matching timing at which the first and second groups of data are output and timing at which a data clock is output, the data clock strobing the first and second groups of data.

15. The memory device of claim 11, wherein:
the first group of data comprises a signal to be stored in the data storage circuit, and
the second group of data comprises a signal comprising error information of the first group of data.

16. The memory device of claim 11, further comprising a repeater configured to generate the internal data from the first group of transfer data and output the internal data to the data storage circuit after the start of the write operation of the training operation and further configured to generate the first group of transfer data from the internal data output by the data storage circuit and output the first group of transfer data after the start of the read operation of the training operation.

17. The memory device of claim 11, wherein the data input and output circuit comprises:
a first group of data transfer circuits configured to generate the first group of transfer data from the first group of data and output the first group of transfer data to a data input and output line after the start of the write operation of the training operation and further configured to generate the first group of data from the first group of transfer data loaded onto the data input and output line and output the first group of data after the start of the read operation of the training operation; and
a second group of data transfer circuits configured to generate the second group of transfer data from the second group of data and output the second group of transfer data to a meta input and output line after the start of the write operation of the training operation and further configured to generate the second group of data from the second group of transfer data loaded onto the meta input and output line and output the second group of data after the start of the read operation of the training operation.

18. The memory device of claim 11, wherein:
the data storage circuit comprises a plurality of banks, and
the data storage circuit is configured to store the internal data in a bank, which is selected from among the plurality of banks based on an address, and output the stored internal data.

19. The memory device of claim 18, wherein:
the meta storage circuit comprises a plurality of registers, and
the meta storage circuit is configured to store the second group of data in a register, which is selected from among the plurality of registers based on the address, and output the stored second group of data.

20. The memory device of claim 19, wherein a number of the plurality of registers included in the meta storage circuit is the same as a number of the plurality of banks included in the data storage circuit.

21. A memory device comprising:
a first data transfer circuit configured to receive first data, store the first data in a write pipe circuit and a read pipe circuit after a start of a write operation of a training operation, and output the first data stored in the read pipe circuit after a start of a read operation of the training operation;
a second data transfer circuit configured to generate transfer data by receiving second data after the start of the write operation of the training operation and further configured to generate the second data from test meta data and output the second data after the start of the read operation of the training operation; and
a meta storage circuit comprising a plurality of registers, and configured to store the transfer data in a register, which is selected from among the plurality of registers based on an address after the start of the write operation of the training operation and configured to output the transfer data stored in the selected register as the test meta data after the start of the read operation of the training operation.

22. The memory device of claim 21, wherein a second transmission characteristic in which the second data are transmitted in the second data transfer circuit has a lower transmission characteristic than a first transmission characteristic in which the first data are transmitted in the first data transfer circuit.

23. The memory device of claim 21, wherein the first data transfer circuit comprises:
a first pad configured to receive the first data after the start of the write operation of the training operation and output first read data as the first data after the start of the read operation of the training operation;
a first parallel conversion circuit configured to generate first write data by receiving the first data through the first pad;
the write pipe circuit configured to store the first write data;
the read pipe circuit configured to store the first write data stored in the write pipe circuit and output the stored first write data as first latch data; and
a first serial conversion circuit configured to generate the first read data by receiving the first latch data and output the first read data to the first pad after the start of the read operation of the training operation.

24. The memory device of claim 21, wherein the second data transfer circuit comprises:
a second pad configured to receive the second data after the start of the write operation of the training operation and output second read data as the second data after the start of the read operation of the training operation;
a second parallel conversion circuit configured to generate second write data by receiving the second data through the second pad;
a first pipe circuit configured to store the second write data;
a driver configured to generate the transfer data from the second write data stored in the first pipe circuit and output the transfer data to a data input and output line;
a multiplexer configured to receive the test meta data loaded onto a meta input and output line after the start of the read operation of the training operation;
a second pipe circuit configured to receive the test meta data through the multiplexer and store the test meta data; and
a second serial conversion circuit configured to generate the second read data by latching the test meta data stored in the second pipe circuit and output the second read data to the second pad.

25. The memory device of claim 24, wherein the meta storage circuit stores the transfer data loaded onto the data input and output line after the start of the write operation of the training operation, and generates the test meta data from the stored transfer data and outputs the test meta data to the meta input and output line after the start of the read operation of the training operation.
